(19) United States
(12) Patent Application Publication
(10) Pub. No.: US 2025/0203761 A1
(43) Pub. Date: Jun. 19, 2025

(54) CIRCUIT BOARD AND SEMICONDUCTOR PACKAGE COMPRISING SAME

(71) Applicant: LG INNOTEK CO., LTD., Seoul (KR)

(72) Inventors: Duck Hoon PARK, Seoul (KR); Hae Sik KIM, Seoul (KR); Jee Heum PAIK, Seoul (KR)

(73) Assignee: LG INNOTEK CO., LTD., Seoul (KR)

(21) Appl. No.: 18/712,570

(22) PCT Filed: Nov. 23, 2022
(86) PCT No.: PCT/KR2022/018626

§ 371 Date: Dec. 6, 2024

(30) Foreign Application Priority Data
Nov. 23, 2021 (KR) 10-2021-0161897

(51) Int. Cl. H05K 1/02; H05K 1/11; H05K 1/18

(52) U.S. Cl. CPC H05K 1/0271; H05K 1/112; H05K 1/181; H05K 2201/091; H05K 2201/09136; H05K 2201/09472; H05K 2201/096; H05K 2201/098; H05K 2201/10212; H05K 2201/10734

(57) ABSTRACT

A circuit board according to an embodiment includes a first insulating layer; a second insulating layer disposed on the first insulating layer; a first electrode part disposed on the second insulating layer; a second electrode part disposed on the first electrode part; a second insulating layer disposed on the second electrode part; and a fourth insulating layer disposed on the third insulating layer, wherein an upper surface of the first insulating layer includes a plurality of first convex parts, wherein a lower surface of the fourth insulating layer includes a plurality of second convex parts, and wherein at least one of distances between adjacent first convex parts among the plurality of first convex parts includes a region different from at least one of distances between adjacent second convex parts among the plurality of second convex parts.

### TECHNICAL FIELD

The embodiment relates to a circuit board and a semiconductor package comprising the same.

### BACKGROUND ART

A printed circuit board (PCB) is formed by printing a circuit line pattern with a conductive material such as copper on an electrically insulating board, and refers to a board before mounting an electronic component. In other words, in order to densely mount many types of electronic devices on a flat plate, it refers to a circuit board that determines a mounting position of each component and fixes the circuit pattern connecting the parts by printing them on the flat surface.

Such a printed circuit board has a multilayer structure. To this end, the conventional manufacturing process of a printed circuit board includes a process of laminating a second insulating layer on the first insulating layer on which the first circuit pattern layer is formed.

However, the second insulating layer of a prior art has a one-layer structure containing a specific insulating material, and as a result, there is a problem that the adhesion between the second insulating layer and the circuit pattern layer and/or the first insulating layer is not secured. Accordingly, in the circuit board of the prior art, a bubble-like void is formed between the circuit pattern layer and the second insulating layer, and the void causes a physical reliability problem in which the second insulating layer is detached from the circuit pattern layer and/or the first insulating layer.

On the other hand, in recent years, in order to automate the manufacturing process of printed circuit boards, a laminating process of a plurality of insulating layers is carried out through a roll-to-roll process using roll-to-roll equipment. And, when the adhesion between the second insulating layer, the circuit pattern layer, and/or the first insulating layer is not secured as described above, there is a problem that it is difficult to manufacture a printed circuit board through a roll-to-roll process.

### DISCLOSURE

### Technical Problem

An embodiment provides a circuit board having a new structure and a semiconductor package including the same.

In addition, the embodiment provides a circuit board in which a convex part is formed at an interface between a plurality of insulating layers and a semiconductor package including the same.

In addition, the embodiment provides a circuit board that can improve efficiency in a process of laminating an insulating layer using a convex part formed on a surface of at least one insulating layer and a semiconductor package including the same.

In addition, the embodiment provides a circuit board that can be manufactured in a roll-to-roll process using a convex part formed on a surface of at least one insulating layer and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a first insulating layer; a second insulating layer disposed on the first insulating layer; a first electrode part disposed on the second insulating layer; a second electrode part disposed on the first electrode part; a second insulating layer disposed on the second electrode part; and a fourth insulating layer disposed on the third insulating layer, wherein an upper surface of the first insulating layer includes a plurality of first convex parts, wherein a lower surface of the fourth insulating layer includes a plurality of second convex parts, and wherein at least one of distances between adjacent first convex parts among the plurality of first convex parts includes a region different from at least one of distances between adjacent second convex parts among the plurality of second convex parts.

In addition, the first convex part is convex toward the first electrode part, and the second convex part is convex toward the second electrode part.

In addition, the first electrode part includes a plurality of first electrodes spaced apart from each other along a horizontal direction, and the second electrode part includes a plurality of second electrodes spaced apart from each other along the horizontal direction, the plurality of first convex parts vertically overlap at least one of the plurality of second electrodes, and the plurality of second convex parts vertically overlap at least one of the plurality of first electrodes.

In addition, each of the plurality of first convex parts is positioned between the plurality of first electrodes, and each of the plurality of second convex parts is positioned between the plurality of second electrodes.

In addition, the second insulating layer and the third insulating layer do not include glass fibers, and the first insulating layer and the fourth insulating layer include glass fibers.

In addition, each of the first to fourth insulating layers includes a filler, a filler content of the first insulating layer is higher than that of the second insulating layer, and a filler content of the fourth insulating layer is higher than that of the third insulating layer.

In addition, the circuit board further comprises an insulating substrate disposed between the first electrode part and the second electrode part.

In addition, the circuit board further comprises a third electrode part disposed under the first insulating layer; and a fourth electrode part disposed on the fourth insulating layer.

In addition, the circuit board further comprises a first through part disposed in the first insulating layer and the second insulating layer; and a second through part disposed in the third insulating layer and the fourth insulating layer, wherein the first through part connects the first electrode part and the third electrode part, and the second through part connects the fourth electrode part and the second electrode part.

In addition, the first through part includes a first-first part passing through the first insulating layer and having a first slope whose width gradually decreases toward the upper surface of the first insulating layer; and a first-second part passing through the second insulating layer and having a second slope different from the first slope whose width gradually decreases toward the upper surface of the second insulating layer.

In addition, an interior angle between a lower surface of the first through part and the first slope is smaller than an interior angle between the lower surface of the first through part and the second slope.

In addition, the second through part includes a second-first part passing through the third insulating layer and having a third slope whose width gradually increases toward an upper surface of the third insulating layer; and a second-second part passing through the fourth insulating layer and having a second slope different from the third slope whose width gradually decreases toward the upper surface of the fourth insulating layer.

In addition, an interior angle between a lower surface of the second through part and the third slope is smaller than an interior angle between a lower surface of the second through part and the fourth slope.

In addition, a lower surface of the first insulating layer includes a region whose height changes to correspond to the plurality of first convex parts, and an uppermost end of the lower surface of the first insulating layer is positioned lower than the lower surface of the first electrode part.

In addition, the second insulating layer includes a second-first insulating layer disposed on the first insulating layer and a second-second insulating layer disposed below the first insulating layer, and the first electrode part is disposed on the second-first insulating layer, and the third electrode part is disposed under the second-second insulating layer.

In addition, the third insulating layer includes a third-first insulating layer disposed under the fourth insulating layer, and a third-second insulating layer disposed on the fourth insulating layer, and the second electrode part is disposed under the third-first insulating layer, and the fourth electrode part is disposed on the third-second insulating layer.

In addition, the upper surface of the third insulating layer includes a region whose height changes to correspond to the plurality of second convex parts, and a lowermost end of the upper surface of the third insulating layer is positioned higher than the upper surface of the second electrode part.

Meanwhile, a semiconductor package according to an embodiment is comprises a first insulating layer; a second insulating layer disposed on the first insulating layer; a first electrode part disposed on the second insulating layer; a second electrode part disposed on the first electrode part; a second insulating layer disposed on the second electrode part; a fourth insulating layer disposed on the third insulating layer, a third electrode part disposed under the first insulating layer; a fourth electrode part disposed on the fourth insulating layer; a connection part disposed on at least one of a plurality of fourth electrodes of the fourth electrode part; a chip mounted on the connection part; and a molding layer covering the chip, wherein an upper surface of the first insulating layer includes a plurality of first convex parts, wherein a lower surface of the fourth insulating layer includes a plurality of second convex parts, and wherein at least one of distances between adjacent first convex parts among the plurality of first convex parts includes a region different from at least one of distances between adjacent second convex parts among the plurality of second convex parts.

### Advantageous Effects

The circuit board of the embodiment includes an insulating substrate, a first substrate layer, and a second substrate layer. Additionally, the circuit board of the embodiment includes a first electrode part disposed on a lower surface of the insulating substrate and a second electrode part disposed on an upper surface of the insulating substrate. At this time, a first substrate layer includes a first insulating layer and a second insulating layer including different materials. At this time, the second insulating layer is disposed closer to the first electrode part than the first insulating layer. Additionally, the first insulating layer includes a first reinforcing fiber and a first filler having a first content. Additionally, the second insulating layer does not include reinforcing fibers and includes a second filler having a second content smaller than the first content. The first insulating layer satisfies the dielectric constant (Dk), dielectric loss (Df), coefficient of thermal expansion (CTE), and Young's modulus (GPa) that the first substrate layer must have. Additionally, the second insulating layer may function to improve fluidity (e.g., resin flowability) of the first substrate layer. For example, when performing a laminating process of the first substrate layer consisting of only the first insulating layer on an insulating substrate, the first substrate layer may not be smoothly filled in a region between the plurality of first electrodes of the first electrode part, and accordingly, the adhesion between the first substrate layer and the first electrode part may be reduced. And, because of this, there is a problem that it is difficult to manufacture circuit boards using a roll-to-roll process. Alternatively, the embodiment allow one insulating layer to include a first insulating layer and a second insulating layer that does not include reinforcing fibers but includes a relatively low content of filler, this allows to improve fluidity in the process of laminating the insulating layer. Through this, the embodiment can secure adhesion between the first electrode part and the first substrate layer, and thereby solve the reliability problem of the first substrate layer being delaminated from the first electrode part. Furthermore, the embodiment can improve fluidity in a process of laminating the insulating layer, and thus it is possible to manufacture circuit boards using a roll-to-roll process. For example, even when a process of laminating an insulating layer is performed using roll-to-roll equipment, the embodiment may laminate the first substrate layer in close contact with the first electrode part. Through this, the embodiment can automate the process of manufacturing a circuit board, thereby reducing manufacturing costs and improving product yield.

Meanwhile, the second substrate layer includes a third insulating layer corresponding to the second insulating layer of the first substrate layer, and a fourth insulating layer corresponding to the first insulating layer of the first substrate layer. Through this, the embodiment can secure fluidity (e.g., resin flowability) in the process of laminating the second substrate layer on the second electrode part, and accordingly, adhesion between the second electrode part and the second substrate layer can be secured.

Additionally, in the embodiment, an upper surface of the first insulating layer or a lower surface of the second insulating layer includes a plurality of first convex parts. In addition, the plurality of first convex parts allow the first substrate layer to smoothly fill a region between the plurality of first electrodes of the first electrode part, in a process of laminating the first substrate layer on the first electrode part. Accordingly, the embodiment can further improve adhesion between the first substrate layer and the first electrode part, and thereby further improve product reliability. Additionally, a plurality of second convex parts are included on a lower surface of the fourth insulating layer or an upper surface of the third insulating layer corresponding to the first substrate layer. Additionally, the plurality of second convex parts allows the second substrate layer to smoothly fill the region between the plurality of second electrodes of the second electrode part, in the process of laminating the second substrate layer on the second electrode part. Accordingly, the embodiment can further improve adhesion between the second substrate layer and the second electrode part, and thereby further improve product reliability.

In addition, at least one of distances between adjacent first convex parts among the plurality of first convex parts in the embodiment includes a region different from at least one of the distances between adjacent second convex parts among the plurality of second convex parts. For example, at least one of the plurality of first convex parts may not vertically overlap with at least one of the plurality of second convex parts. Through this, the embodiment can improve adhesion between a lower roll and the first substrate layer by using at least one of the plurality of second convex parts of the second substrate layer. In addition, the embodiment can improve adhesion between the second substrate layer and an upper roll by using at least one of the plurality of first convex parts of the first substrate layer. Accordingly, the embodiment can further improve the adhesion between the first electrode part and the first substrate layer, and the adhesion between the second electrode part and the second substrate layer.

Meanwhile, a first through part is formed in the first substrate layer of the embodiment. At this time, the first through part includes a first-first part passing through the first insulating layer and a first-second part passing through the second insulating layer. At this time, the first-first part of the first through part has a first slope, and the first-second part has a second slope different from the first slope. For example, an interior angle of the second slope with respect to a lower surface of the first through part is greater than an interior angle of the first slope with respect to a lower surface of the first through part. At this time, a through part in a comparative example includes only the first slope, and accordingly, a width of the upper and lower surfaces of the through part has a “A” level. Alternatively, the first through part of the embodiment includes the first slope and the second slope, and accordingly, a width of the upper surface and the lower surface of the first through part may have a level of “B” smaller than that of the comparative example. Accordingly, the embodiment can minimize a difference between the widths of the upper surface and the lower surface of the first through part, and through this, it is possible to refine a size of the first through part. Furthermore, the embodiment minimizes the loss of a signal transmitting through the first through part by minimizing the difference between the width of the upper surface and the lower surface of the first through part, thereby improving signal characteristics. Additionally, a second through part having a symmetrical shape to the first through part is formed in the second substrate layer. Accordingly, the embodiment can minimize a difference between widths of an upper surface and a lower surface of the second through part, and through this, a size of the second through part can be refined and signal characteristics can be improved.

### DESCRIPTION OF DRAWINGS

FIG. 1A is a view showing a circuit board according to a comparative example.

FIG. 1B is a view for explaining a process of laminating an insulating layer in a circuit board of a comparative example.

FIG. 1C is a view showing voids occurring in a circuit board according to a comparative example.

FIG. 2A is a view showing a circuit board according to a first embodiment.

FIG. 2B is a view showing a micrograph of an actual product according to FIG. 2a.

FIGS. 3A and 3B are enlarged views of a first substrate layer of FIG. 2A.

FIG. 3C is an enlarged view of a second substrate layer of FIG. 2A.

FIG. 4A is an enlarged view of a first through part of FIG. 2A.

FIG. 4B is an enlarged view of the second through part of FIG. 2A.

FIG. 5 is a view showing a circuit board according to a second embodiment.

FIG. 6 is a view showing a circuit board according to a third embodiment.

FIG. 7 is a view showing a circuit board according to a fourth embodiment.

FIG. 8 is a view showing a circuit board according to a fifth embodiment.

FIG. 9 is a view showing a circuit board according to a fifth embodiment.

FIG. 10 is a view showing a semiconductor package according to an embodiment.

FIGS. 11A to 11E are views for explaining a method of manufacturing the circuit board shown in FIG. 2A in order of processes.

### BEST MODE

Hereinafter, preferred embodiments of the present invention will be described in detail with reference to the accompanying drawings.

However, the technical spirit of the present invention is not limited to some embodiments described, but may be implemented in various different forms, and, as long as it is within the scope of the technical spirit of the present invention, one or more of the components may be selectively combined and substituted between the embodiments.

In addition, terms (including technical and scientific terms) used in the embodiments of the present invention may be interpreted as meanings that can be generally understood by those of ordinary skill in the art to which the present invention pertains unless explicitly defined and described, and the meanings of commonly used terms such as predefined terms may be interpreted in consideration of the contextual meaning of the related art. In addition, the terms used in the embodiments of the present invention are for describing the embodiments and are not intended to limit the present invention.

In this specification, the singular may also include the plural unless specifically stated in the phrase, and when it is described as “A and (and) at least one (or more than one) of B and C”, it may include one or more of all combinations that can be combined with A, B, and C. In addition, in describing the components of the embodiment of the present invention, terms such as first, second, A, B, (a), (b), etc. may be used.

These terms are only used to distinguish the component from other components, and are not limited to the essence, order, or order of the component by the term. And, when it is described that a component is ‘connected’, ‘coupled’ or ‘contacted’ to another component, the component is not only directly connected, coupled or contacted to the other component, but also with the component it may also include a case of ‘connected’, ‘coupled’ or ‘contacted’ due to another element between the other elements.

In addition, when it is described as being formed or disposed on “above (on) or below (under)” of each component, the above (on) or below (under) is one as well as when two components are in direct contact with each other. Also includes a case in which another component as described above is formed or disposed between two components. In addition, when expressed as “above (up) or below (under)”, it may include not only the upward direction but also the meaning of the downward direction based on one component.

### Comparative Example (Structure and Problems of Prior Art)

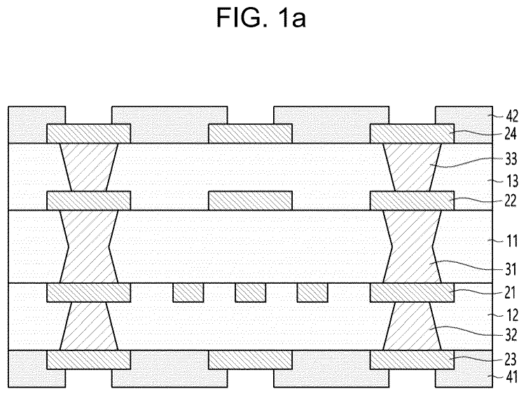

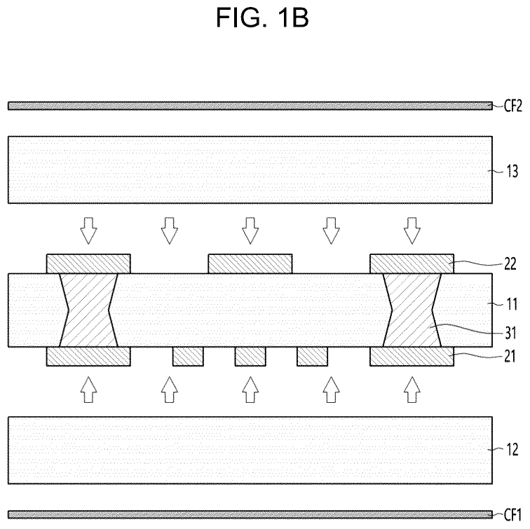

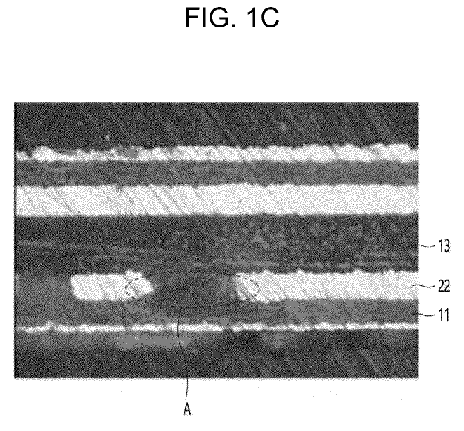

FIG. 1A is a view showing a circuit board according to a comparative example, FIG. 1B is a view for explaining a process of laminating an insulating layer in a circuit board of a comparative example, FIG. 1C is a view showing voids occurring in a circuit board according to a comparative example.

Referring to FIG. 1A, a circuit board according to the comparative example includes an insulating layer, an electrode part, a through part, and a protective layer.

The insulating layer of the circuit board of the comparative example includes a first insulating layer 11, a second insulating layer 12, and a third insulating layer 13.

The first insulating layer 11 refers to an insulating layer disposed at an inside of a plurality of laminate structures of the circuit board. The second insulating layer 12 is disposed under the first insulating layer 11, and the third insulating layer 13 is disposed on the first insulating layer 11.

The electrode part in the comparative example includes a first electrode part 21 disposed on a lower surface of the first insulating layer 11, a second electrode part 22 disposed on an upper surface of the first insulating layer 11, a third electrode part 23 disposed on a lower surface of the second insulating layer 12 and a fourth electrode part 24 disposed on an upper surface of the third insulating layer 13.

The through part in the comparative example includes a first through part 31 disposed in a through hole passing through the first insulating layer 11, a second through part 32 disposed in a through hole passing through the second insulating layer 12. a third through part 33 disposed in a through hole passing through the third insulating layer 13.

The protective layer in the comparative example includes a first protective layer 41 disposed on a lower surface of the second insulating layer 12 and a second protective layer 42 disposed on an upper surface of the third insulating layer 13.

At this time, the first insulating layer 11 in the comparative example may mean a core layer. In addition, the second insulating layer 12 and the third insulating layer 13 may refer to build-up insulating layers laminated on and under the first insulating layer 11, respectively.

At this time, an insulating layer applied to the circuit board applied to the flip chip BGA (Ball Grid Array) package, etc., requires a certain level of characteristic values. The characteristic values may include dielectric constant (Dk), dielectric loss (Df), coefficient of thermal expansion (CTE), and Young's modulus (GPa) of the insulating layer.

Specifically, a specific range of characteristic values required for the circuit board is shown in Table 1 below.

TABLE 1

| | | | coefficient of | |
|---|---|---|---|---|
| | | | thermal | |
| | dielectric | dielectric loss | expansion | Young's |
| | constant (Dk) | (Df) | (CTE) | modulus (GPa) |
| Reference | 3.0 to 4.5 | 0.002 to 0.1 | 4 to 13 | 25 to 35 |
| range | | | | |

Accordingly, in the comparative example, the second insulating layer 12 and the third insulating layer 13 in the circuit board are formed with prepreg containing reinforcing fibers to satisfy each characteristic value as shown in Table 1. However, the insulating layer containing the above prepreg has relatively low fluidity (e.g., resin flowability) due to heat or press pressure compared to RCC (resin coated copper) or ABF (Ajinomoto build up film) that do not contain reinforcing fibers. Here, the fluidity can also be expressed as the resin flowability or wetting of the insulating layer. Accordingly, the fluidity of the second insulating layer 12 and the third insulating layer 13 is low, and Accordingly, in the process of manufacturing the circuit board of the comparative example, the adhesion between the first insulating layer 11, the second insulating layer 12, and the third insulating layer 13 is reduced. Accordingly, a problem occurs in which the second insulating layer 12 or the third insulating layer 13 is delaminated from the first insulating layer 11. Additionally, the delamination problem may be more severe when manufacturing a circuit board using a roll-to-roll process, which may make it impossible to manufacture a circuit board using a roll-to-roll process.

Specifically, referring to FIG. 1B, a process of manufacturing the circuit board of FIG. 1A includes a first process of forming a first electrode part 21, a second electrode part 22, and a first through part 31 in the first insulating layer 11. Then, when the first process is completed, a build-up process of laminating the second insulating layer 12 and the third insulating layer 13 by applying heat or press pressure is performed after the second insulating layer 12 and the first copper foil layer CF1 are located under the first insulating layer 11, the third insulating layer 13 and the second copper foil layer CF2 are located on the first insulating layer 11.

At this time, as described above, there is a problem that the second insulating layer 12 and the third insulating layer 13 have relatively low fluidity and cannot be laminated in close contact with the first insulating layer 11.

Specifically, the second insulating layer 12 is laminated on the lower surface of the first insulating layer 11 and the lower surface of the first electrode part 21. Accordingly, the second insulating layer 12 includes a first region vertically overlapping the first electrode part 21 and a second region excluding the first region.

At this time, the first region and the second region may have a step. Additionally, the step between the first region and the second region may correspond to a thickness of the first electrode part 21 depending on the manufacturing method.

And, in the process of laminating the second insulating layer 12, due to the low fluidity of the prepreg, there is a problem that the adhesion of the second insulating layer 12 decreases at the boundary region between the first region and the second region. Specifically, there is a problem that the second insulating layer 12 is not sufficiently adhered to the boundary region between the first region and the second region (e.g., the region where the step starts or a region adjacent to a side surface of the first electrode part). For example, as the second insulating layer 12 of the comparative example has low fluidity, the adhesion between the second insulating layer 12 and the side surface of the first electrode part 21 decreases. And, this problem also occurs between the third insulating layer 13 and the second electrode part 22.

Accordingly, as shown in FIG. 1C, in the circuit board of the comparative example, voids A such as bubbles are generated between the first insulating layer 11 and the second insulating layer 12 or between the first insulating layer 11 and the third insulating layer 13. In addition, the void A degrades the adhesion between the first insulating layer 11 and the second insulating layer 12 or between the first insulating layer 11 and the third insulating layer 13, thereby causing a physical reliability problem in which the second insulating layer 12 or the third insulating layer 13 is delaminated from the first insulating layer 11.

To solve this problem, the second insulating layer 12 and the third insulating layer 13 may be configured using RCC or ABF, which has better fluidity than the prepreg. However, when the second insulating layer 12 and the third insulating layer 13 consist of RCC or ABF, there is a problem in that dielectric constant Dk, dielectric loss Df, coefficient of thermal expansion CTE, and Young's modulus GPa are not satisfied as shown in Table 1.

Accordingly, the embodiment provides an insulating layer with a new laminate structure capable of ensuring adhesion to an electrode while satisfying the dielectric constant (Dk), dielectric loss (Df), thermal expansion coefficient (CTE), and Young's modulus (GPa) in Table 1.

### —Electronic Device—

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package. The semiconductor package may include memory chips such as volatile memory (e.g., DRAM), non-volatile memory (e.g., ROM), and flash memory, application processor chips such as central processors (e.g., CPUs), graphics processors (e.g., GPUs), digital signal processors, encryption processors, microprocessors, and microcontrollers, and logic chips such as analog-to-digital converters and application-specific ICs (ASICs).

In addition, the embodiment provides a semiconductor package capable of mounting at least two or more chips of different types on one substrate while reducing the thickness of the semiconductor package connected to the main board of the electronic device above. Accordingly, the embodiment may make it easier to transmit signals or power between a plurality of chips, thereby achieving miniaturization of an electronic device.

In this case, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### First Embodiment

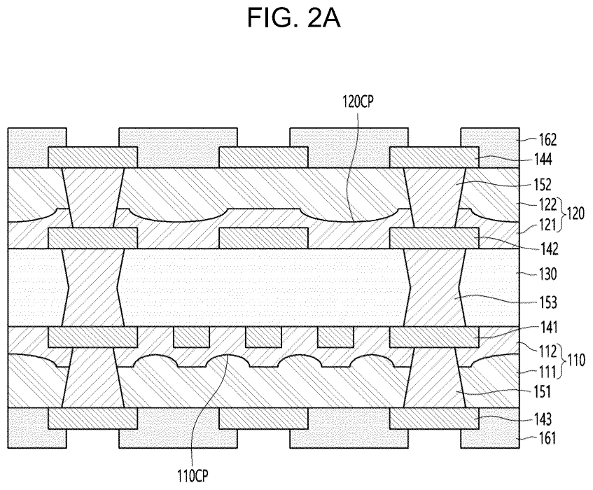

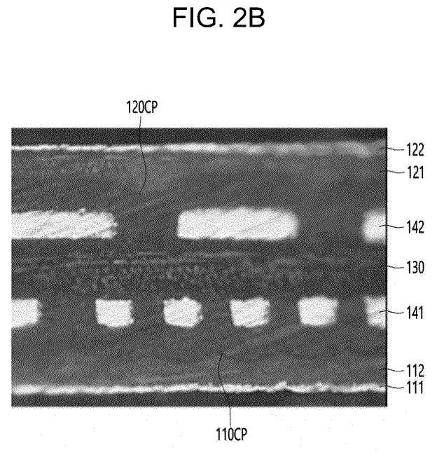

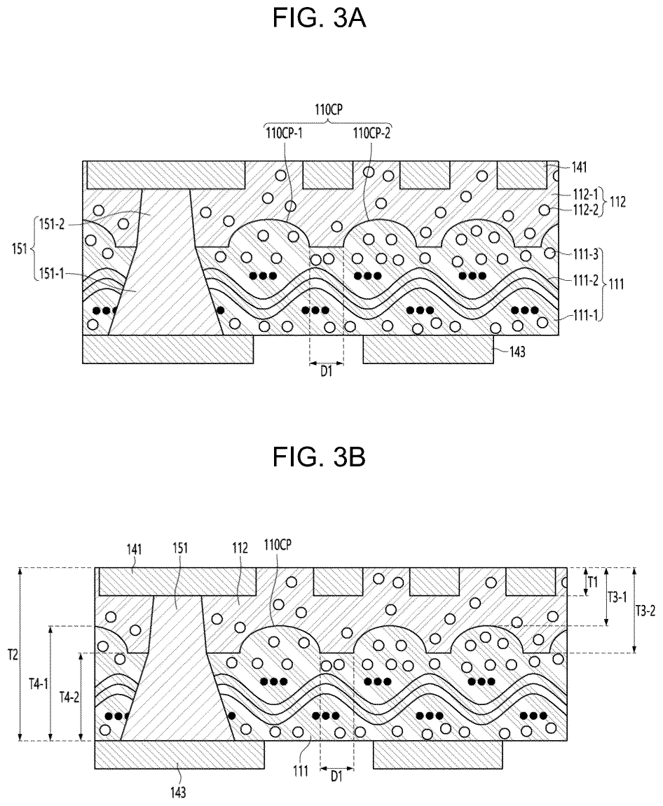

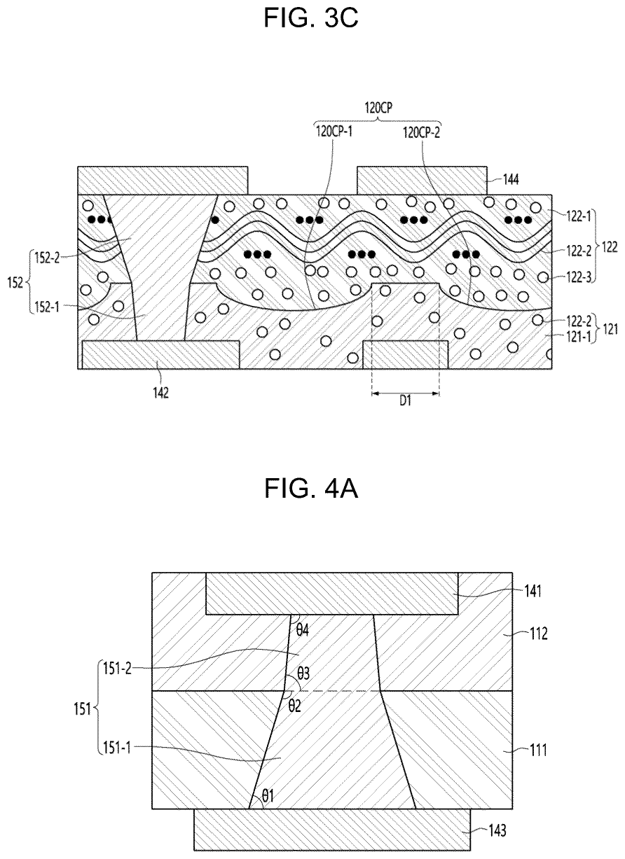

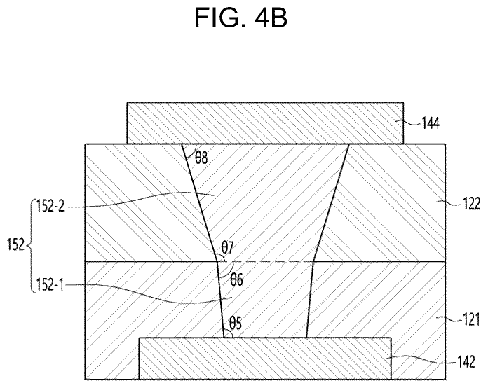

FIG. 2A is a view showing a circuit board according to a first embodiment, FIG. 2B is a view showing a micrograph of an actual product according to FIG. 2a, FIGS. 3A and 3B are enlarged views of a first substrate layer of FIG. 2A, FIG. 3C is an enlarged view of a second substrate layer of FIG. 2A, FIG. 4A is an enlarged view of a first through part of FIG. 2A, and FIG. 4B is an enlarged view of the second through part of FIG. 2A.

Hereinafter, a circuit board according to a first embodiment will be described in detail with reference to FIGS. 2A, 2B, 3A, 3B, 3C, 4A, and 4B.

Meanwhile, in the drawing, the circuit board of the first embodiment is shown to have a four-layer structure based on the number of layers of the electrode part, but is not limited thereto. For example, a circuit board may have five or more layers based on the number of layers of the electrode part.

The circuit board may include a first substrate layer 110, a second substrate layer 120, and an insulating substrate 130 based on an insulating layer.

The insulating substrate 130 may refer to an insulating layer disposed at an inside of a laminate structure of a circuit board. For example, the insulating substrate 130 may refer to a core layer, but is not limited thereto. For example, when the insulating substrate 130 is a core layer, the circuit board of an embodiment may be a core substrate. Alternatively, the circuit board of an embodiment may be a coreless substrate. However, hereinafter, for convenience of explanation, it will be described that the insulating substrate 130 is a core layer.

The insulating substrate 130 is disposed at the center or inside of the circuit board, and accordingly, stability against the overall warpage of the circuit board may be maintained.

The insulating substrate 130 may include a prepreg. For example, the insulating substrate 130 may be a copper clad laminate (CCL) including a prepreg, but is not limited thereto.

Meanwhile, a first electrode part 141 is disposed on a lower surface of the insulating substrate 130. Also, a second electrode part 142 is disposed on an upper surface of the insulating substrate 130. For example, a first electrode part 141 including a plurality of first electrodes spaced apart from each other in the horizontal direction is disposed on the lower surface of the insulating substrate 130. Also, a second electrode part 142 including a plurality of second electrodes spaced apart from each other in the horizontal direction is disposed on the upper surface of the insulating substrate 130. This will be described in more detail below.

Meanwhile, a first substrate layer 110 may be disposed under the insulating substrate 130, and a second substrate layer 120 may be disposed over the insulating substrate 130.

The first substrate layer 110 may mean a lower insulating layer disposed under the insulating substrate 130. The second substrate layer 120 may mean an upper insulating layer disposed on the insulating substrate 130.

In this case, in the first embodiment, the first substrate layer 110 may have a plurality of layer structures. For example, in the comparative example of FIG. 1A, the second insulating layer 12 corresponding to the first substrate layer 110 has a single layer structure including a prepreg, and thus adhesion between the second insulating layer 12 and the electrode part or the insulating substrate is not secured.

In contrast, the first substrate layer 110 of the embodiment has a plurality of layer structures, so that the adhesion between the first substrate layer 110 and the insulating substrate 130 and the adhesion between the first substrate layer 110 and the first electrode part 141 can be secured.

Specifically, the first substrate layer 110 may include a first insulating layer 111 and a second insulating layer 112.

The first insulating layer 111 may mean an insulating layer relatively far from the insulating substrate 130 among a plurality of insulating layers constituting the first substrate layer 110. For example, the first insulating layer 111 may mean an insulating layer relatively far from the first electrode part 141 among a plurality of insulating layers constituting the first substrate layer 110.

The second insulating layer 112 may be disposed on the first insulating layer 111. For example, the second insulating layer 112 may mean an insulating layer disposed adjacent to the insulating substrate 130 among a plurality of insulating layers constituting the first substrate layer 110. For example, the second insulating layer 112 may mean an insulating layer disposed adjacent to the first electrode part 141 among a plurality of insulating layers constituting the first substrate layer 110.

Accordingly, the first insulating layer 111 may not be in direct physical contact with the insulating substrate 130 and the first electrode part 141. And, the second insulating layer 112 may be in direct physical contact with the insulating substrate 130 and the first electrode part 141. For example, the second insulating layer 112 may be in direct contact with a lower surface of the insulating substrate 130, a side surface of the first electrode part 141, and a lower surface of the first electrode part 141. For example, the second insulating layer 112 may be formed on a lower surface of the insulating substrate 130 to cover the side surface of the first electrode part 141 and the lower surface of the first electrode part 141.

The first insulating layer 111 and the second insulating layer 112 constituting the first substrate layer 110 may include different materials.

For example, the first insulating layer 111 may be formed as a prepreg. For example, the first insulating layer 111 may include a first resin 111-1, a first reinforcing fiber 111-2, and a first filler 111-3.

Specifically, the first insulating layer 111 may have a structure in which a first resin (111-1, e.g., an epoxy resin) is impregnated with a fiber layer in a form of a fabric sheet such as a first reinforcing fiber 111-2 woven with a glass fiber thread. However, the first reinforcing fiber 111-2 of the first insulating layer 111 may include a fiber layer in the form of a fabric sheet woven with carbon fiber yarn other than glass fiber. Also, the first filler 111-3 may be dispersed and disposed in the first resin 111-1 of the first insulating layer 111-1.

The first resin 111-1 of the first insulating layer 111-1 may be an epoxy resin, but is not limited thereto. The first resin 111-1 is not particularly limited to the epoxy resin, and for example, one or more epoxy groups may be included in the molecule, or alternatively, two or more epoxy groups may be included, or alternatively, four or more epoxy groups may be included. In addition, the first resin 111-1 of the first substrate layer 110 may include a naphthalene group, for example, may be an aromatic amine type, but is not limited thereto. For example, the first resin 111-1 may be include a bisphenol A type epoxy resin, a bisphenol F type epoxy resin, a bisphenol S type epoxy resin, a phenol novolac type epoxy resin, an alkylphenol novolac type epoxy resin, a biphenyl type epoxy resin, an aralkyl type epoxy resin, dicyclopentadiene type epoxy resin, naphthalene type epoxy resin, naphthol type epoxy resin, epoxy resin of condensate of phenol and aromatic aldehyde having phenolic hydroxyl group, biphenyl aralkyl type epoxy resin, fluorene type epoxy resin resins, xanthene-type epoxy resins, triglycidyl isocyanurate, rubber-modified epoxy resins, phosphorous-based epoxy resins, and the like, and naphthalene-based epoxy resins, bisphenol A-type epoxy resins, and phenol novolac epoxy resins, cresol novolak epoxy resins, rubber-modified epoxy resins, and phosphorous-based epoxy resins.

In addition, the first reinforcing fiber 111-2 may include glass fiber, carbon fiber, aramid fiber (e.g., aramid-based organic material), nylon, silica-based inorganic material or titania-based inorganic material. The reinforcing fibers may be arranged in the first resin 111-1 to cross each other in a planar direction.

The first insulating layer 111 may include a first filler 111-3 disposed together with the first reinforcing fiber 111-2 in the first resin 111-1. The first filler 111-3 may be a ceramic filler. For example, the first filler 111-3 may be formed of a ceramic material of any one of SiO₂, ZrO₃, HfO₂, and TiO₂. However, the embodiment is not limited thereto, and the first filler 111-3 of the first insulating layer 111 may be formed of another material, in addition to the ceramic material, for allowing the first substrate layer 110 to satisfy the characteristic value as shown in Table 1.

Meanwhile, the first filler 111-3 in the first insulating layer 111 may be disposed with a first content. For example, the first content of the first filler 111-3 in the first insulating layer 111 may be 51 to 80 wt %. For example, the first content of the first filler 111-3 in the first insulating layer 111 may satisfy 55 to 75 wt %. In the first insulating layer 111, when the first content of the first filler 111-3 is less than 51 or exceeds 80 wt %, the first substrate layer 110 may not satisfy a characteristic value as shown in Table 1.

The second insulating layer 112 may include a material different from a material of the first insulating layer 111. In detail, the second insulating layer 112 may not include the first reinforcing fiber included in the first insulating layer 111.

Specifically, the second insulating layer 112 may include a second resin 112-1 and a second filler 112-2 disposed in the second resin 112-1. That is, a reinforcing fiber is not included in the second resin 112-1 of the second insulating layer 112. That is, the first substrate layer 110 of the embodiment includes different materials for respective regions in a thickness direction. In addition, the first substrate layer 110 prevents the reinforcing fiber such as the glass fiber from being included in the second insulating layer 112 disposed in a region adjacent to the insulating substrate 130 and the first electrode part 141. Accordingly, in an embodiment, fluidity of the first substrate layer 110 may be improved by using the second insulating layer 112, thereby ensuring adhesion between the insulating substrate 130 or the first electrode part 141.

The second resin 112-1 of the second insulating layer 112 may be an epoxy resin, but is not limited thereto. Preferably, in the process of laminating the first substrate layer 110 on the first electrode part 141, the second insulating layer 112-1 functions to improve the fluidity of the first substrate layer 110, and to this end, the second resin 112-1 of the second insulating layer 112 may include a solid epoxy and a liquid epoxy. Accordingly, in an embodiment, since the first substrate layer 110 includes the second insulating layer 112, adhesion between the first electrode part 141 and the first substrate layer 110 may be secured, and thus a circuit board may be manufactured by a roll-to-roll process. That is, when the roll-to-roll process is applied for the manufacture of the circuit board, a structure of the present embodiment may secure adhesion between the second insulating layer 112, the insulating substrate 130 and the first insulating layer 111, thereby enabling the manufacture of a stable structure.

For example, the second insulating layer 112 may include a solid epoxy including epoxy-novolac resins or the like, and a second resin 112-1 including a liquid epoxy including Bisphenol A diglyceryl ether or the like. In this case, a content of the solid epoxy of the second resin 112-1 in the second insulating layer 112 may satisfy 15 wt % to 50 wt %. Also, a content of the liquid epoxy of the second resin 112-1 in the second insulating layer 112 may satisfy 5 wt % to 20 wt %. When the content of the solid epoxy is 15 wt % or less, the first substrate layer 110 including the second insulating layer 112 may not satisfy the characteristic values in Table 1. Also, when the content of the solid epoxy is more than 50 wt %, fluidity of the first substrate layer 110 by the second insulating layer 112 may not be secured, and thus, an effect of increasing adhesion between the first substrate layer 110 and the insulating substrate 130 and the first electrode part 141 may be insufficient. Furthermore, when the content of the liquid epoxy is less than 5 wt %, fluidity of the first substrate layer 110 is not secured by the second insulating layer 112, and thus voids such as bubbles may be generated between the first electrode part 141 and the second insulating layer 112. Furthermore, when the content of the liquid epoxy exceeds 20 wt %, the first substrate layer 110 including the second insulating layer 112 may not satisfy the characteristic values shown in Table 1.

Meanwhile, a second filler 112-2 having a second content is disposed in the second resin 112-1 of the second insulating layer 112. In this case, the second content of the second filler 112-2 in the second insulating layer 112 may be less than the first content of the first filler 111-3 in the first insulating layer 111. Preferably, as the second content of the second filler 112-2 included in the second insulating layer 112 decreases, fluidity of the second insulating layer 112 may be improved. Preferably, the second content of the second filler 112-2 in the second insulating layer 112 may be 10 wt % to 50 wt %. For example, the second content of the second filler 112-2 in the second insulating layer 112 may be 15 wt % to 45 wt %. For example, the second content of the second filler 112-2 in the second insulating layer 112 may be 20 wt % to 40 wt %. When the second content of the second filler 112-2 in the second insulating layer 112 is less than 10 wt %, the first substrate layer 110 including the second insulating layer 112 may not satisfy the characteristic value as shown in Table 1. When the second content of the second filler 112-2 in the second insulating layer 112 is less than 10 wt %, warpage characteristics of the circuit board may be deteriorated. Also, when the second content of the second filler 112-2 in the second insulating layer 112 is more than 50 wt %, fluidity of the first substrate layer 110 by the second insulating layer 112 is not secured, and thus, a reliability problem of including voids such as bubbles may occur between the second insulating layer 112 and the first electrode part 141. Meanwhile, the second insulating layer 112 may further include an amine-type curing agent.

As described above, in the embodiment, the first substrate layer 110 is divided into a plurality of regions in the thickness direction, and accordingly, an insulating layer including different materials in each region is formed.

In addition, the embodiment allows the first substrate layer 110 to satisfy the characteristic values as shown in Table 1 through the first insulating layer 111 of the first substrate layer 110. In addition, the embodiment enables fluidity to be secured in a process of laminating the first substrate layer 110 under the insulating substrate 130 by using the second insulating layer 112 of the first substrate layer 110, thereby ensuring adhesion between the second insulating layer 112, the insulating substrate 130 and the first insulating layer 111. In addition, when the roll-to-roll process is applied, the structure of the present embodiment may secure adhesion between the second insulating layer 112, the insulating substrate 130 and the first insulating layer 111, so that a stable structure may be manufactured.

Meanwhile, the first substrate layer 110 of the first embodiment includes a first convex part 110CP. Preferably, a first convex part 110CP may be provided at an interface between a plurality of insulating layers constituting the first substrate layer 110. Here, the convex part means not only a convex structure toward the insulating substrate 130 but also a concave structure toward the insulating substrate 130 (e.g., convex in a direction away from the insulating substrate 130), and this is referred to as a convex part for convenience, but does not limit only a convex structure toward the insulating substrate 130.

Preferably, a plurality of first convex parts 110CPs may be formed on the upper surface of the first insulating layer 111 facing the lower surface of the second insulating layer 112. For example, a plurality of first convex parts 110CPs may be formed on the lower surface of the second insulating layer 112 facing the upper surface of the first insulating layer 111. That is, the plurality of first convex parts 110CPs may be formed on the upper surface of the first insulating layer 111 and differently, may be formed on the lower surface of the second insulating layer 112. Hereinafter, for convenience of explanation, the description will be made assuming that the plurality of first convex parts 110CP are formed on the upper surface of the first insulating layer 111.

On the other hand, the regions of the upper surface of the first insulating layer 111 and the lower surface of the second insulating layer 112 except for the region where the first convex part 110CP is formed are shown to be flat, but are not limited thereto. For example, the regions of the upper surface of the first insulating layer 111 and the lower surface of the second insulating layer 112 except for the region where the first convex part 110CP is formed may have a convex shape in a direction opposite to a convex direction of the first convex part.

A plurality of first convex parts 110CP formed on the upper surface of the first insulating layer 111 in the first embodiment may be convex toward the insulating substrate 130. For example, the first convex part 110CP may be convex toward the first electrode part 141. Accordingly, the first convex part 110CP may also be referred to as a concave part with respect to the lower surface of the first insulating layer 111.

For example, the upper surface of the first insulating layer 111 may include a region in which a height of the upper surface of the first insulating layer 111 changes in the horizontal direction. And, the first convex part 110CP may mean a region in which the height of the upper surface of the first insulating layer 111 changes.

In an embodiment, a plurality of first convex parts 110CP are formed on the upper surface of the first insulating layer 111, thereby ensuring adhesion between the first substrate layer 110 and the insulating substrate 130 and the first electrode part 141. In addition, in an embodiment, even when the first substrate layer 110 including the first insulating layer 111 and the second insulating layer 112 is laminated using a roll-to-roll process, adhesion between the first substrate layer 110 and the insulating substrate 130 and the first electrode part 141 may be secured.

In this case, the plurality of first convex parts 110CP of the first embodiment may be formed based on a position of the first electrode part 141 disposed on a lower surface of the insulating substrate 130 (e.g., formed according to a topology of the first electrode part).

Specifically, the plurality of first convex parts 110CP of the first embodiment may vertically overlap a region (e.g., a region that does not vertically overlap the first electrodes) between the plurality of first electrodes constituting the first electrode part 141.

For example, the first convex part 110CP includes a convex part that is convex toward the first electrode part 141. In addition, an outer region of a convex portion of the first convex part 110CP may vertically overlap the first electrode part 141. Also, remaining regions of the convex portion of the first convex part 110CP except for the outer region may not vertically overlap the first electrode part 141. Specifically, an uppermost portion of the convex parts of the first convex part 110CP of the first embodiment may not vertically overlap the first electrode part 141.

For example, the first convex part 110CP may be formed to correspond to a region between a plurality of first electrodes of the first electrode part 141. For example, the first convex part 110CP may vertically overlap a region between a plurality of first electrodes of the first electrode part 141. In addition, in an embodiment, in the process of laminating the first substrate layer 110, the adhesion between the first substrate layer 110 and the first electrode part 141 may be improved by using the first convex part 110CP. Accordingly, in an embodiment, even when the first substrate layer 110 is laminated by applying a roll-to-roll process, adhesion between the first substrate layer 110 and the insulating substrate 130 and the first electrode part 141 may be secured.

Specifically, in a process of laminating the first substrate layer 110 on the first electrode part 141, adhesion may be deteriorated in a region (preferably an edge region of the first electrode or a side region of the first electrode) between a plurality of first electrodes of the first electrode part 141. As a result, voids such as bubbles may occur in the region between the plurality of first electrodes. In this case, in the embodiment, the region between a plurality of first electrodes of the first electrode part 141 vertically overlaps the first convex part 110CP. And, the first convex part 110CP functions to increase the fluidity of the first substrate layer 110 in the region between a plurality of first electrodes of the first electrode part 141, thereby improving adhesion between the first substrate layer 110 and the insulating substrate 130 and the first electrode part 141.

In this case, the first convex part 110CP may be formed when the second insulating layer 112 of the first substrate layer 110 includes only the second filler 112-2 of the second content without including the reinforcing fiber as described above.

For example, the first convex part 110CP of the first embodiment may be formed to correspond to the first electrode part 141 after the lamination of the first substrate layer 110 is completed on the first electrode part 141, and unlike this, may be formed to correspond to the first electrode part 141 before the process of laminating the first substrate layer 110 is performed.

Specifically, the first convex part 110CP may not be included on the upper surface of the first insulating layer 111 or the lower surface of the second insulating layer 112 before the first substrate layer 110 is laminated on the first electrode part 141. And, when the process of laminating the first substrate layer 110 is performed in the state in which the first insulating layer 111 and the second insulating layer 112 are disposed on the lower surface of the insulating substrate 130, the second insulating layer 112 may fill a region between the plurality of first electrodes. And, as the second insulating layer 112 fills the region between the plurality of first electrodes, a plurality of first convex parts 110CP corresponding to the upper surface of the first insulating layer 111 or the lower surface of the second insulating layer 112 may be formed.

Alternatively, the first convex part 110CP may be included in the upper surface of the first insulating layer 111 or the lower surface of the second insulating layer 112 before the process of laminating the first substrate layer 110 is performed. For example, in the first embodiment, a process of laminating the first substrate layer 110CP may be performed in a state in which the first convex part 110CP is formed on the lower surface of the second insulating layer 112 to correspond to the positions of the plurality of first electrodes of the first electrode part 141. And, as the process of laminating the first substrate layer 110 in a state in which the first convex part 110CP is formed, a plurality of first convex parts 110CP may be formed on the upper surface of the first insulating layer 111 to correspond to the lower surface of the second insulating layer 112.

Meanwhile, the first convex part 110CP of the first embodiment may correspond to positions of a plurality of first electrodes of the first electrode part 141. Accordingly, the first convex part 110CP of the first embodiment may vertically overlap at least one of a plurality of second electrodes of the second electrode part 142 disposed on the upper surface of the insulating substrate 130. For example, an uppermost end of at least one of a plurality of first convex parts 110CP may vertically overlap at least one of a plurality of second electrodes of the second electrode part 142.

Meanwhile, the first insulating layer 111 and the second insulating layer 112 may have different thicknesses. For example, a thickness of the first insulating layer 111 may be greater than a thickness of the second insulating layer 112.

For example, a second thickness T2 of the first substrate layer 110 including the first insulating layer 111 and the second insulating layer 112 may be determined by the first thickness T1 of the first electrode part 141. In this case, the second thickness T2 of the first substrate layer 110 may mean a vertical distance between an upper surface of the first electrode part 141 and a lower surface of the first insulating layer 111.

The second thickness T2 of the first substrate layer 110 may satisfy a range between 200% and 400% of a first thickness T1 of the first electrode part 141. For example, the second thickness T2 of the first substrate layer 110 may satisfy a range between 220% and 380% of the first thickness T1 of the first electrode part 141. The second thickness T2 of the first substrate layer 110 may satisfy a range between 250% and 350% of the first thickness T1 of the first electrode part 141.

The first thickness T1 of the first electrode part 141 may satisfy a range of 8 μm to 20 μm. And the second thickness T2 of the first substrate layer 110 may satisfy a range of 16 μm to 80 μm.

When the second thickness T2 of the first substrate layer 110 is less than 200% of the first thickness T1 of the first electrode part 141 or less than 16 μm, the first electrode part 141 may not be stably protected by the first substrate layer 110. And, when the second thickness T2 of the first substrate layer 110 exceeds 400% of the first thickness T1 of the first electrode part 141 or exceeds 80 μm, the overall thickness of the circuit board may increase.

Meanwhile, the thickness of the second insulating layer 112 may be greater than the thickness T1 of the first electrode part 141. For example, the thickness of the second insulating layer 112 may satisfy 110 to 150% of the thickness T1 of the first electrode part 141. In this case, the second insulating layer 112 may have different thicknesses for each region. For example, the second insulating layer 112 may have a third-first thickness T3-1 in a region vertically overlapping the first convex part 110CP. And, the second insulating layer 112 may have a third-second thickness T3-2 in a region that does not vertically overlap the first convex part 110CP. And, the thickness of the second insulating layer 112 may mean an average value of the third-first thickness T3-1 and the third-second thickness T3-2. Alternatively, the thickness of the second insulating layer 112 may mean a third-first thickness T3-1 that is a thickness of a region vertically overlapping the first convex part 110CP.

In this case, if the thickness of the second insulating layer 112 is less than 110% of the thickness T1 of the first electrode part 141, the effect of increasing fluidity may be insufficient in the structure including the second insulating layer 112 and the first convex part 110CP according to the embodiment.

For example, if the thickness of the second insulating layer 112 is less than 110% of the thickness T1 of the first electrode part 141, a height of the uppermost end of the first convex part 110CP may be located higher than a height of the lower surface of the first electrode part 141. And, if the uppermost end of the first convex part 110CP is located higher than the lower surface of the first electrode part 141, the fluidity may deteriorate in the region between a plurality of first electrodes of the first electrode part 141. As a result, voids such as bubbles may occur in the process of laminating the first substrate layer 110. Also, if the thickness of the second insulating layer 112 exceeds 150% of the thickness T1 of the first electrode part 141, the first substrate layer 110 including the second insulating layer 112 may not satisfy the characteristic value as shown in Table 1.

Meanwhile, the thickness of the first insulating layer 111 may be greater than the thickness T1 of the first electrode part 141 and the thickness of the second insulating layer 112. For example, the thickness of the first insulating layer 111 may satisfy 150 to 290% of the thickness T1 of the first electrode part 141.

In this case, the first insulating layer 111 may have different thicknesses for each region. For example, the first insulating layer 111 may have a fourth-first thickness T4-1 in a region vertically overlapping the first convex part 110CP. And, the first insulating layer 111 may have a fourth-second thickness T4-2 in a region not vertically overlapping the first convex part 110CP. And, the thickness of the first insulating layer 111 may mean an average value of the fourth-first thickness T4-1 and the fourth-second thickness T4-2.

In the thickness of the insulation region from the lower surface of the first electrode part 141 to the lower surface of the first insulation layer 111, the thickness of the first insulation layer 111 may satisfy a range of 60% to 95%. Also, in the thickness of the insulation region of the first substrate layer 110, the thickness of the second insulation layer 112 may satisfy a range of 5% to 40%.

That is, the first substrate layer 110 of an embodiment includes a first insulating layer 111 and a second insulating layer 112. The second insulating layer 112 may function to improve fluidity of the first substrate layer 110. Further, the first insulating layer 111 allows the overall characteristic value of the first substrate layer 110 to satisfy the characteristic value as shown in Table 1.

For example, as the thickness of the second insulating layer 112 increases, the dielectric constant (Dk), dielectric loss (Df), and coefficient of thermal expansion (CTE) of the first substrate layer 110 increase, and the Young's modulus (GPa) increases.

In this case, the embodiment allows dielectric constant (Dk), dielectric loss (Df), coefficient of thermal expansion (CTE), and Young's modulus (GPa) of the first substrate layer 110 to have a level similar to that of a general prepreg while allowing the first substrate layer 110 to include the second insulating layer 112. To this end, in an embodiment, in the insulation region of the first substrate layer 110, the thickness of the first insulating layer 111 is 1.5 to 13 times greater than that of the second insulating layer 112.

And, if the thickness of the first insulating layer 111 in the insulating region of the first substrate layer 110 is less than 1.5 times that of the second insulating layer 112, the first substrate layer 110 may not satisfy the characteristic value of Table 1. For example, if the thickness of the first insulating layer 111 is less than 1.5 times that of the second insulating layer 112, the dielectric constant (Dk) of the first substrate layer 110 may be low, the dielectric loss (Df) may be low, the coefficient of thermal expansion (CTE) may be low, or the Young's modulus (GPa) may be high with respect to the characteristic value of Table 1.

In addition, if the thickness of the first insulating layer 111 in the insulating region of the first substrate layer 110 exceeds 13 times that of the second insulating layer 112, the effect of increasing the fluidity of the first substrate layer 110 by the second insulating layer 112 may be insufficient, and thus the insulating layer may be laminated in a state in which voids such as bubbles are generated. Thus, it may be difficult to manufacture a circuit board through a roll-to-roll process. In addition, if the thickness of the first insulating layer 111 in the insulating region of the first substrate layer 110 exceeds 13 times that of the second insulating layer 112, the overall thickness of the circuit board may increase.

Meanwhile, in an embodiment, for convenience of description, the first substrate layer 110 is classified as including a first insulating layer 111 and a second insulating layer 112. In this case, the first insulating layer 111 and the second insulating layer 112 may substantially constitute one insulating part. In detail, an electrode part is not disposed between the first insulating layer 111 and the second insulating layer 112. For example, only the first through part 151 is disposed in the first insulating layer 111 and the second insulating layer 112. For example, an electrode part other than the first through part 151 is not disposed between the first insulating layer 111 and the second insulating layer 112.

Meanwhile, the second substrate layer 120 may have a structure corresponding to the first substrate layer 110.

For example, the second substrate layer 120 may include a third insulating layer 121 disposed on the second electrode part 142 and a fourth insulating layer 122 disposed on the third insulating layer 121.

And, the third insulating layer 121 of the second substrate layer 120 may correspond to the second insulating layer 112 of the first substrate layer 110. Also, the fourth insulating layer 122 of the second substrate layer 120 may correspond to the first insulating layer 111 of the first substrate layer 110.

For example, the third insulating layer 121 may include a third resin 121-1 corresponding to the second resin 112-1 of the second insulating layer 112 and a third filler 121-2 corresponding to the second filler 112-2 of the second insulating layer 112. In this case, the characteristics of the third resin 121-1 and the third filler 121-2 correspond to the second resin 112-1 and the second filler 112-2, and thus a detailed description thereof will be omitted.

In addition, the fourth insulating layer 122 may include a fourth resin 122-1 corresponding to the first resin 111-1 of the first insulating layer 111, a second reinforcing fiber 122-2 corresponding to the first reinforcing fiber 111-2 of the first insulating layer 111, and a fourth filler 122-3 corresponding to the first filler 111-3 of the first insulating layer 111. In addition, the characteristics of the fourth resin 122-1, the second reinforcing fiber 122-2 and the fourth filler 122-3 of the fourth insulating layer 122 correspond to the characteristics of the first resin 111-1, the first reinforcing fiber 111-2 and the first filler 111-3 of the first insulating layer 111, and accordingly, detailed description thereof will be omitted.

Meanwhile, a thickness of the second electrode part 142 corresponds to a thickness of the first electrode part 141, a thickness of the second substrate layer 120 corresponds to a thickness of the first substrate layer 110, a thickness of the third insulating layer 121 corresponds to a thickness of the second insulating layer 112, and a thickness of the fourth insulating layer 122 corresponds to a thickness of the first insulating layer 111. Thus, a detailed description thereof will be omitted.

Meanwhile, the second substrate layer 120 of the first embodiment includes a second convex part 120CP. Preferably, a second convex part 120CP may be included in an interface between a plurality of insulating layers constituting the second substrate layer 120.

Preferably, a plurality of second convex parts 120CP may be formed on a lower surface of the fourth insulating layer 122 facing an upper surface of the third insulating layer 121. For example, a plurality of second convex parts 120CP may be formed on an upper surface of the third insulating layer 121 facing a lower surface of the fourth insulating layer 122. That is, the plurality of second convex parts 120CP may be formed on the upper surface of the third insulating layer 121 and differently, may be formed on the lower surface of the fourth insulating layer 122. Hereinafter, for convenience of explanation, it will be described that the plurality of second convex parts 120CP are formed on the lower surface of the fourth insulating layer 122.

A plurality of second convex parts 120CP formed on the lower surface of the fourth insulating layer 121 of the first embodiment may be convex toward the insulating substrate 130. For example, the second convex part 120CP may be convex toward the second electrode part 142. Accordingly, the second convex part 120CP may also be referred to as a concave part with respect to the upper surface of the fourth insulating layer 122.

For example, the lower surface of the fourth insulating layer 122 may include a region in which the height of the fourth insulating layer 122 changes in the horizontal direction. And, the second convex part 120CP may mean a region in which the height of the lower surface of the fourth insulating layer 122 changes.

In an embodiment, a plurality of second convex parts 120CP are formed on the lower surface of the fourth insulating layer 122 so that adhesion between the second substrate layer 120, the insulating substrate 130 and the second electrode part 142 may be secured in the process of laminating the second substrate layer 120 including the third insulating layer 121 and the fourth insulating layer 122. Accordingly, a roll-to-roll process may be applied so that a process of laminating the second substrate layer 120 may be performed.

In this case, the plurality of second convex parts 120CP of the first embodiment may be formed based on the position of the second electrode part 142 disposed on the upper surface of the insulating substrate 130.

Specifically, the plurality of second convex parts 120CP of the first embodiment may vertically overlap a region between the plurality of second electrodes constituting the second electrode part 142.

For example, the second convex part 120CP includes a convex part that is convex toward the second electrode part 142. In addition, an outer region of the convex portion of the second convex part 120CP may vertically overlap the second electrode part 142. Also, the remaining regions of the convex portion of the second convex part 120CP except for the outer region may not vertically overlap the second electrode part 142. Specifically, a lowermost portion of the convex portions of the second convex part 120CP of the first embodiment may not vertically overlap the second electrode part 142.

For example, the second convex part 120CP may be formed to correspond to a region between a plurality of second electrodes of the second electrode part 142. For example, the second convex part 120CP may vertically overlap a region between a plurality of second electrodes of the second electrode part 142. In addition, in an embodiment, adhesion between the second substrate layer 120 and the insulating substrate 130 the second electrode part 142 may be improved during a process of laminating the second substrate layer 120 using the second convex part 120CP. Accordingly, an embodiment may improve adhesion between the second substrate layer 120 and the insulating substrate 130 and the second electrode part 142. In an embodiment, even when the second substrate layer 120 is laminated by applying a roll-to-roll process, adhesion between the second substrate 120 and the insulating substrate 130 and the second electrode part 142 may be secured.

Specifically, in the process of laminating the second substrate layer 120 on the second electrode part 142, adhesion may be deteriorated in a region (preferably an edge region of the second electrode or a side region of the second electrode) between a plurality of second electrodes of the second electrode part 142. Accordingly, voids such as bubbles may occur in the region between the plurality of second electrodes. In this case, in an embodiment, the region between a plurality of second electrodes of the second electrode part 142 vertically overlaps the second convex part 120CP. And, the second convex part 120CP functions to increase the fluidity of the second substrate layer 120 in the region between a plurality of second electrodes of the second electrode part 142, thereby improving adhesion between the second substrate layer 120 and insulating substrate 130 and the second electrode part 142.

In this case, the second convex part 120CP may be formed when only the third filler 121-2 of the second content is included in the third resin 121-1 without including the reinforcing fiber as described above.

For example, the second convex part 120CP of the first embodiment may be formed to correspond to the second electrode part 142 after the lamination of the second substrate layer 120 is completed on the second electrode part 142, or may be formed to correspond to the second electrode part 142 before the process of laminating the second substrate layer 120 proceeds.

Specifically, the second convex part 120CP may not be included on the upper surface of the third insulating layer 121 or the lower surface of the fourth insulating layer 122 before the second substrate layer 110 is laminated on the second electrode part 142. And, as the process of laminating the second substrate layer 120 in the state in which the third insulating layer 121 and the fourth insulating layer 122 are disposed on the upper surface of the insulating substrate 130 proceeds, the third insulating layer 121 fills the region between the plurality of second electrodes, and a plurality of second convex parts 120CP may be formed on the upper surface of the third insulating layer 121 or the lower surface of the fourth insulating layer 122.

Alternatively, the second convex part 120CP may be included in the upper surface of the third insulating layer 121 or the lower surface of the fourth insulating layer 122 before the process of laminating the second substrate layer 120 proceeds. For example, in the first embodiment, a process of laminating the second substrate layer 120CP may be performed in a state in which the second convex part 120CP is formed on the upper surface of the third insulating layer 121 or the lower surface of the fourth insulating layer 122 to correspond to the positions of the plurality of second electrodes of the second electrode part 142. And, as the process of laminating the second substrate layer 120 in the state in which the first convex part 110CP is formed, a plurality of second convex parts 120CP may be formed on the upper surface of the third insulating layer 121 and the lower surface of the fourth insulating layer 122 corresponding thereto.

Meanwhile, the second convex part 120CP of the first embodiment may correspond to positions of a plurality of second electrodes of the second electrode part 142. Accordingly, the second convex part 120CP of the first embodiment may vertically overlap at least one of a plurality of first electrodes of the first electrode part 141 disposed on the lower surface of the insulating substrate 130. For example, a lowermost end of at least one of a plurality of second convex parts 120CP may vertically overlap at least one of a plurality of first electrodes of the first electrode part 141.

On the other hand, at least one of distances between the first convex parts closest to each other in the plurality of first convex parts 110CP of the first substrate layer 110 may be different from at least one of distances between the second convex parts closest to each other in the plurality of second convex parts 120CP of the second substrate layer 120.

Specifically, the plurality of first convex parts 110CP may include a first-first convex part 110CP-1 and a first-second convex part 110CP-2 which are closest to each other. And, the first-first convex part 110CP-1 and the first-second convex part 110CP-2 may be spaced apart from each other by a first distance D1. In this case, the first distance D1 may mean a horizontal distance between one end of the first-first convex part 110CP-1 and the other end of the first-second convex part 110CP-2.

Also, the plurality of second convex parts 120CP may include a second-first convex part 120CP-1 and a second-second convex part 120CP-2, which are closest to each other. And, the second-first convex part 120CP-1 and the second-second convex part 120CP-2 may be spaced apart from each other by a second distance D2. In this case, the second distance D2 may mean a horizontal distance between one end of the second-first convex part 120CP-1 and the other end of the second-second convex part 120CP-2.

In this case, the first distance D1 may be different from the second distance D2.

Here, the first distance D1 may correspond to a distance between the first electrodes of the first electrode part 141, and the second distance D2 may correspond to the second electrodes of the second electrode part 142. And, at least one of the distances between the first electrodes of the first electrode part 141 may be different from at least another of the distances between the second electrodes of the second electrode part 142. Accordingly, the first distance D1 may be different from the second distance D2.

In addition, when the first distance D1 and the second distance D2 are different, it means that at least one of the plurality of first convex parts 110CPs does not vertically overlap at least one of the plurality of second convex parts 120CPs.

Furthermore, the embodiment prevents at least one of the plurality of first convex parts 110CPs and at least one of the plurality of second convex parts 120CPs from vertically overlapping, thereby further improving the fluidity of the first substrate layer 110 and the second substrate layer 120. Furthermore, the embodiment enables the flowability of the first substrate layer 110 and the second substrate layer 120 to be simultaneously laminated by applying a roll-to-roll process.

For example, a roll-to-roll equipment includes a lower roll and an upper roll (not shown). In this case, in the case of performing the lamination process using the roll-to-roll equipment, at least one of the second convex part 120CP formed on the second substrate layer 120 may increase a pressing force between the first substrate layer 110 and the lower roll facing the first substrate layer 110. Accordingly, an embodiment may further improve the adhesion between the first substrate layer 110 and the insulating substrate.

Meanwhile, a third electrode part 143 is disposed on the lower surface of the first substrate layer 110. For example, a third electrode part 143 is disposed on the lower surface of the first insulating layer 111. Also, a fourth electrode part 144 is disposed on the upper surface of the second substrate layer 120. For example, a fourth electrode part 144 is disposed on the upper surface of the fourth insulating layer 122.

The first electrode part 141, the second electrode part 142, the third electrode part 143, and the fourth electrode part 144 may mean wiring patterns for signal transmission. The first electrode part 141, the second electrode part 142, the third electrode part 143, and the fourth electrode part 144 may be formed of at least one metal material selected from among gold (Au), silver (Ag), platinum (Pt), titanium (Ti), tin (Sn), copper (Cu), and zinc (Zn).

In addition, the first electrode part 141, the second electrode part 142, the third electrode part 143, and the fourth electrode part 144 may be formed of a paste or a solder paste containing at least one metallic material selected from among gold (Au), silver (Ag), platinum (Pt), titanium (Ti), tin (Sn), copper (Cu), and zinc (Zn) having excellent bonding power. Preferably, the first electrode part 141, the second electrode part 142, the third electrode part 143, and the fourth electrode part 144 may be formed of copper (Cu) which has high electrical conductivity and is relatively inexpensive.

The first electrode part 141, the second electrode part 142, the third electrode part 143, and the fourth electrode part 144 can be used as an additive process, a subtractive process, MSAP (Modified Semi Additive Process), and SAP (Semi Additive Process), which are typical circuit board manufacturing processes, and detailed explanations are omitted here.

Meanwhile, the circuit board of the embodiment includes a through part. The through part may passes through the insulating layer and electrically connect electrode parts disposed on different layers.

Preferably, a first through part 151 is disposed in the first substrate layer 110. For example, a first through part 151 is disposed in the first insulating layer 111 and the second insulating layer 112 of the first substrate layer 110. For example, the first through part 151 may passes through the first insulating layer 111 and the second insulating layer 112. The first through part 151 may electrically connect between the first electrode part 141 disposed on the upper surface of the second insulating layer 112 or the lower surface of the insulating substrate 130 and the third electrode part 143 disposed on the lower surface of the first insulating layer 111.

A second through part 152 is disposed in the second substrate layer 120. For example, a second through part 152 is disposed in the third and fourth insulating layers 121 and 122 of the second substrate layer 120. For example, the second through part 152 may passes through the third and fourth insulating layers 121 and 122. The second through part 152 may electrically connect the second electrode part 142 disposed on the lower surface of the third insulating layer 121 or the upper surface of the insulating substrate 130 with the fourth electrode part 144 disposed on the upper surface of the fourth insulating layer 122.

A third through part 153 is disposed in the insulating substrate 130. The third through part 153 may pass through the insulating substrate 130. The third through part 153 may electrically connect the first electrode part 141 disposed on the lower surface of the insulating substrate 130 and the second electrode part 142 disposed on the upper surface of the insulating substrate 130.

The first through part 151, the second through part 152, and the third through part 153 may be formed by filling the inside of the through hole (not shown) passing through the first substrate layer 110, the second substrate layer 120, and the insulating substrate 130 with a conductive material.

In this case, the through hole may be formed by any one of mechanical, laser, and chemical processing. When the through hole is formed by machining, it can be formed using methods such as milling, drilling, and routing. When the through hole is formed by laser processing, it can be formed using methods such as UV or CO₂ laser. When the through hole is formed by chemical processing, it can be formed using a chemical containing amino silane, ketones, or the like.

Meanwhile, the laser processing is a cutting method that concentrates optical energy on a surface to melt and evaporate a part of the material to take a desired shape, accordingly, complex formations by computer programs can be easily processed, and even composite materials that are difficult to cut by other methods can be processed.

In addition, the laser processing has a cutting diameter of at least 0.005 mm, and has a wide range of possible thicknesses.

As the laser processing drill, it is preferable to use a YAG (Yttrium Aluminum Garnet) laser, a CO₂ laser, or an ultraviolet (UV) laser. YAG laser is a laser that can process both copper foil layers and insulating layers, and CO₂ laser is a laser that can process only insulating layers.

When the through hole passing through at least one of the first substrate layer 110, the second substrate layer 120, and the insulating substrate 130 is formed, the first through part 151, the second through part 152, and the third through part 153 may be formed by filling the inside of the through hole with a conductive material. The metal material forming the first through part 151, the second through part 152, and the third through part 153 may be any one material selected from copper (Cu), silver (Ag), tin (Sn), gold (Au), nickel (Ni), and palladium (Pd). In addition, the conductive material filling may use any one or a combination of electroless plating, electrolytic plating, screen printing, sputtering, evaporation, ink-jetting and dispensing.

Meanwhile, the first through part 151, the second through part 152, and the third through part 153 may each include a plurality of slopes.

In this case, the third through part 153 is formed in the insulating substrate 130 which is a core layer. When the insulating substrate 130 is a core layer, the insulating substrate 130 may have a thickness of 100 μm or more. Accordingly, a through hole may be formed in the insulating substrate 130 through a plurality of laser processes. For example, since the insulating substrate 130 has a thickness equal to or greater than a predetermined thickness, it is difficult to form a through hole penetrating the insulating substrate 130 by only one laser process, and accordingly, a first laser process is performed on an upper side of the insulating substrate 130, and a second laser process is performed on a lower side of the insulating substrate 130. Accordingly, an hour-shaped through hole may be formed in the insulating substrate 130 through two laser processes. Accordingly, the third through part 153 may have an hourglass shape corresponding to the through hole. Accordingly, the third through part 153 may include a plurality of slopes. For example, the third through part 153 may include a first slope whose width is gradually decreased toward the lower surface of the insulating substrate 130 while being adjacent to the upper surface of the insulating substrate 130, and a second slope whose width is gradually decreased toward the upper surface of the insulating substrate 130 while being adjacent to the lower surface of the insulating substrate 130. However, the embodiment is not limited thereto. For example, if the insulating substrate 130 is not a core layer or a through hole penetrating the insulating substrate 130 can be formed through a single laser process, the third through part 153 may only have a first slope whose width gradually decreases from the upper surface to the lower surface or a second slope whose width gradually increases from the upper surface to the lower surface.

Meanwhile, each of the first through part 151 and the second through part 152 of the embodiment may include a plurality of slopes. Here, the slope may mean a slope of each of the side surfaces of the first through part 151 and the second through part 152.

Specifically, the first through part 151 passes through the first substrate layer 110. In this case, the first substrate layer 110 includes a first insulating layer 111 and a second insulating layer 112. Accordingly, the first through part 151 may include a first-first part 151-1 passes through the first insulating layer 111 and a first-second part 151-2 passes through the second insulating layer 112. In this case, the first insulating layer 111 and the second insulating layer 112 include different materials. For example, the first insulating layer 111 includes a reinforcing fiber, and the second insulating layer 112 does not include a reinforcing fiber. Also, a first content of the first filler 111-3 included in the first insulating layer 111 is greater than a second content of the second filler 112-2 included in the second insulating layer 112. Accordingly, the first-first part 151-1 and the first-second part 151-2 may have different slopes.

The first-first part 151-1 may be disposed in the first insulating layer 111 and may have a first slope whose width changes toward the second insulating layer 112. For example, the first-first part 151-1 may have a first slope whose width gradually decreases toward the second insulating layer 112. In this case, the first slope may mean a slope of the side surface of the first-first part 151-1. More specifically, the first slope may mean a slope of the side surface of the first-first part 151-1 with respect to a lower surface of the first through part 151. Unlike this, the first slope may mean a slope of the side surface of the first-first part 151-1 with respect to the lower surface of the first insulating layer 111.

The first insulating layer 111 includes a first reinforcing fiber 111-2. Accordingly, when the through-hole passing through the first insulating layer 111 is formed through the laser processing method, the intensity of the laser beam decreases as the distance from the lower surface of the first insulating layer 111 increases, and accordingly, a first through-hole having a first slope in which the width gradually decreases toward an upper side may be formed in the first insulating layer 111. Accordingly, the first-first part 151-1 disposed in a first through-hole of the first insulating layer 111 may have a first slope in which the width gradually decreases toward an upper side.

Meanwhile, the first-second part 151-2 may be disposed in the second insulating layer 112 and may have a second slope whose width changes toward the upper surface of the second insulating layer 112 or the insulating substrate 130. For example, the first-second part 151-2 may have a second slope whose width gradually decreases toward the upper surface of the second insulating layer 112 or the insulating substrate 130. In this case, the second slope may mean the slope of the side surface of the first-second part 151-2. More specifically, the second slope may mean the slope of the side surface of the first-second part 151-2 with respect to the lower surface of the first through part 151. Unlike this, the first slope may mean the slope of the side surface of the first-second part 151-2 with respect to the lower surface of the first insulating layer 111.

Unlike the first insulating layer 111, the second insulating layer 112 does not include reinforcing fiber and includes a relatively small amount of filler. Accordingly, when the through hole penetrating the second insulating layer 112 is formed through the laser processing method, a laser beam having a uniform intensity in a depth direction 111 may be provided to the second insulating layer 112, compared to the first insulating layer. In this case, although the intensity of the laser beam provided to the second insulating layer 112 decreases toward the upper surface thereof, the degree of reduction in the intensity of the laser beam is smaller than the degree of reduction in the intensity of the laser beam provided to the first insulating layer 111. Accordingly, a second through hole having a second slope whose width decreases toward the upper surface of the second insulating layer 112 is formed in the second insulating layer 112. In this case, a second slope of the second through hole formed in the second insulating layer 112 is different from a first slope of the first through hole formed in the first insulating layer 111. In this case, the first slope and the second slope may be slopes inclined in the same direction. However, due to the difference in materials constituting the first insulating layer 111 and the second insulating layer 112, the slope of the first through hole formed in the first insulating layer 111 and the slope of the second through hole formed in the second insulating layer 112 may be different from each other.

Accordingly, the first-second part 151-2 disposed in the second through hole of the second insulating layer 112 may have a second slope different from the first slope while a width thereof is gradually decreased in an upward direction. For example, the first slope is smaller than the second slope.

In this case, the through part in the comparative example includes only one slope. For example, the through part in the comparative example includes only the first slope. Accordingly, the through part in the comparative example has a problem in that the difference between the width of the upper surface and the width of the lower surface is relatively large. And, as the difference between the width of the upper surface and the width of the lower surface of the through part increases, there is a problem that it is difficult to form a fine-sized through part. In addition, as the difference between the width of the upper surface and the width of the lower surface of the through part increases, there is a problem that signal transmission loss increases, and communication characteristics deteriorate accordingly.

Alternatively, the first through part 151 of the embodiment includes a first-first part 151-1 having a first slope and a first-second part 151-2 having a second slope different from the first slope. In addition, the second slope is greater than the first slope. Accordingly, the embodiment may reduce the difference between the upper surface width and the lower surface width of the first through part 151 compared to the comparative example, corresponding to the difference between the first slope and the second slope. Accordingly, the embodiment may improve signal transmission characteristics by minimizing signal transmission loss while miniaturizing the first through part 151.

Specifically, referring to FIG. 4A, the first slope may mean a first interior angle θ1 between the lower and side surfaces of the first-first part 151-1. Alternatively, the first slope may mean a second interior angle θ2 between the upper and side surfaces of the first-first part 151-1. For example, the second slope may mean a third interior angle θ3 between the lower and side surfaces of the first-second part 151-2. Alternatively, the second slope may mean a fourth interior angle θ4 between the upper and side surfaces of the first-second part 151-2.

The first interior angle θ1 with respect to the first slope of the first-first part 151-1 is smaller than the third interior angle θ3 with respect to the second slope of the first-second part 151-2. For example, the first interior angle θ1 may satisfy a range between 70 degrees and 85 degrees. For example, the first interior angle θ1 may satisfy a range between 72 degrees and 83 degrees. In addition, the third interior angle θ3 may be larger than the first interior angle θ1 and may satisfy a range between 80 degrees and 89 degrees. For example, the third interior angle θ3 is larger than the first interior angle θ1 and may satisfy a range between 82 degrees and 88 degrees. At this time, the slope of the through part in the comparative example has only the first interior angle θ1, and accordingly, the difference between the width of the upper surface and the width of the lower surface of the through part is relatively large compared to the present embodiment. Alternatively, in an embodiment, the slope of the first through part 151 includes a first slope corresponding to the first interior angle θ1 and a second slope corresponding to the third interior angle θ3, and accordingly, a difference between the width of the upper surface and the width of the lower surface of the first through part 151 may be reduced compared to the comparative example.

Meanwhile, the second interior angle θ2 with respect to the first slope of the first-first part 151-1 is larger than the fourth interior angle θ4 with respect to the second slope of the first-second part 151-2. For example, the second interior angle θ2 may satisfy a range between 95 and 110 degrees. For example, the second interior angle θ2 may satisfy a range between 97 and 108 degrees. In addition, the fourth interior angle θ4 may be smaller than the second interior angle θ2 and may satisfy a range between 91 and 100 degrees. For example, the fourth interior angle θ4 may be smaller than the second interior angle θ2 and may satisfy a range between 92 and 98 degrees. Accordingly, an embodiment may reduce a difference between a width of an upper surface and a width of the lower surface of the first through part 151 compared to a comparative example, and accordingly, it is possible to miniaturize the first through part 151 and improve signal transmission characteristics.

Meanwhile, the second through part 152 may have a shape corresponding to the first through part 151. For example, the second through part 152 may have a shape symmetrical to the first through part 151 with respect to the insulating substrate 130.

Specifically, the second through part 152 may include a second-first part 152-1 penetrating the third insulating layer 121 and a second-second part 152-2 penetrating the fourth insulating layer 122. In addition, the second-first part 152-1 of the second through part 152 may have a symmetrical shape with the first-second part 151-2 of the first through part 151. Also, the second-second part 152-2 of the second through part 152 may have a symmetrical shape with the first-first part 151-1 of the first through part 151.

Specifically, the second through part 152 passes through the second substrate layer 120. In this case, the second substrate layer 120 includes a third insulating layer 121 and a fourth insulating layer 122. Accordingly, the second through part 152 may include a second-first part 152-1 penetrating the third insulating layer 121 and a second-second part 152-2 penetrating the fourth insulating layer 122. In this case, the third insulating layer 121 and the fourth insulating layer 122 include different materials. For example, the fourth insulating layer 122 includes a reinforcing fiber, and the reinforcing fiber is not included in the third insulating layer 121. Also, a first content of the fourth filler 122-3 included in the fourth insulating layer 122 is greater than a second content of the third filler 121-2 included in the third insulating layer 121. Accordingly, the second-first part 152-1 and the second-second part 152-2 may have different slopes.

The second-first part 152-1 may be disposed in the third insulating layer 121, and may have a third slope whose width changes toward the lower surface of the third insulating layer 112 or the insulating substrate 130. For example, the second-first part 152-1 may have a third slope whose width gradually decreases toward the lower surface of the third insulating layer 121 or the insulating substrate 130. In this case, the third slope may mean the slope of the side surface of the second-first part 152-1. Specifically, the third slope may mean the slope of the side surface of the second-first part 152-1 with respect to the lower surface of the second through part 152. Unlike this, the third slope may mean the slope of the side surface of the second-first part 152-1 with respect to the lower surface of the third insulating layer 121.

The second-second part 152-2 may be disposed in the fourth insulating layer 122 and have a fourth slope whose width changes toward the third insulating layer 121 or the insulating substrate 130. For example, the second-second part 152-2 may have a fourth slope whose width gradually decreases toward the third insulating layer 121. In this case, the fourth slope may mean a slope of the side surface of the second-second part 152-2.

In this case, the fourth insulating layer 122 includes a second reinforcing fiber 122-2. Accordingly, when the through-hole penetrating the fourth insulating layer 122 is formed through the laser processing method, the intensity of the laser beam decreases as the distance from the upper surface of the fourth insulating layer 122 increases, and thus, a fourth through-hole having a fourth slope in which the width gradually decreases toward a lower side may be formed in the fourth insulating layer 122. Accordingly, the second-second part 152-2 disposed in the fourth through-hole of the fourth insulating layer 122 may have a fourth slope in which the width gradually decreases toward the lower side.

Unlike this, unlike the fourth insulating layer 122, the third insulating layer 121 does not include a reinforcing fiber and includes a relatively small amount of a filler. Accordingly, when the through hole penetrating the third insulating layer 121 is formed through the laser processing method, a laser beam having a uniform intensity in a depth direction compared to the fourth insulating layer 122 may be provided to the third insulating layer 121. In this case, although the intensity of the laser beam provided to the third insulating layer 121 decreases toward the lower surface from the upper surface of the third insulating layer 121, the degree of reduction in the intensity of the laser beam provided to the third insulating layer 121 is smaller than the degree of reduction in the intensity of the laser beam provided to the fourth insulating layer 122. Accordingly, a third through hole having a third slope whose width decreases toward the lower surface of the third insulating layer 121 is formed in the third insulating layer 121. In this case, the third slope of the third through hole formed in the third insulating layer 121 is different from the fourth slope of the fourth through hole formed in the fourth insulating layer 122. In this case, the third slope and the fifth slope may be slopes inclined in the same direction. However, due to the difference between materials constituting the third insulating layer 121 and the fourth insulating layer 122, the third slope of the third through hole formed in the third insulating layer 121 and the fourth slope of the fourth through hole formed in the fourth insulating layer 122 may be different from each other.

Specifically, referring to FIG. 4B, the third slope may mean a fifth interior angle θ5 between the lower and side surfaces of the second-first part 152-1. Alternatively, the third slope may mean a sixth interior angle θ6 between the upper and side surfaces of the second-first part 152-1. For example, the fourth slope may mean a seventh interior angle θ7 between the lower and side surfaces of the second-second part 152-2. Alternatively, the second slope may mean an eighth interior angle θ8 between the upper and side surfaces of the second-second part 152-2.

The fifth interior angle θ5 with respect to the third slope of the second-first part 152-1 is smaller than the seventh interior angle θ7 with respect to the fourth slope of the second-second part 152-2. For example, the fifth interior angle θ5 may be smaller than the seventh interior angle θ7 and may satisfy a range between 91 and 100 degrees. For example, the fifth interior angle θ5 may be larger than the seventh interior angle θ7 and may satisfy a range between 92 and 98 degrees. For example, the seventh interior angle θ7 may satisfy a range between 95 and 110 degrees. For example, the seventh interior angle θ7 may satisfy a range between 97 and 108 degrees.

In addition, the sixth interior angle θ6 with respect to the third slope of the second-first part 152-1 is larger than the eighth interior angle θ8 with respect to the fourth slope of the second-second part 152-2.

For example, the sixth interior angle θ6 may be greater than the eighth interior angle θ8 and may satisfy a range between 80 degrees and 89 degrees. For example, the sixth interior angle θ6 may be greater than the eighth interior angle θ8 and may satisfy a range between 82 degrees and 88 degrees. For example, the eighth interior angle θ8 may satisfy a range between 70 degrees and 85 degrees. For example, the eighth interior angle θ8 may satisfy a range between 72 degrees and 83 degrees.

Accordingly, the embodiment may minimize the difference between the width of the upper surface and the width of the lower surface of the second through part 152 compared to the comparative example, thereby improving signal transmission characteristics while refining the size of the second through part 152.

Meanwhile, the circuit board of an embodiment includes a protective layer. Specifically, a first protective layer 161 is formed on the lower surface of the first substrate layer 110. For example, the first protective layer 161 is formed on the lower surface of the first insulating layer 111 of the first substrate layer 110. The first protective layer 161 may include at least one first opening (not shown). For example, the first protective layer 161 may include a first opening vertically overlapping at least one of a plurality of third electrodes of the third electrode part 143. The first protective layer 161 may protect the lower surface of the first insulating layer 111 and at least one of the plurality of third electrodes.

Also, a second protective layer 162 is formed on the upper surface of the second substrate layer 120. For example, the second protective layer 162 is formed on the upper surface of the fourth insulating layer 122. The second protective layer 162 may include at least one second opening (not shown). For example, the second protective layer 162 may include a second opening vertically overlapping at least one of a plurality of fourth electrodes of the fourth electrode part 144. The second protective layer 162 may protect an upper surface of the fourth insulating layer 122 and at least one of the plurality of fourth electrodes.

Meanwhile, the first protective layer 161 and the second protective layer 162 may include an insulating material. The first protective layer 161 and the second protective layer 162 may include various materials that may be cured by being applied to protect surfaces of the third electrode part 143 and the fourth electrode part 144 and then heated. The first protective layer 161 and the second protective layer 162 may be resist layers. For example, the first protective layer 161 and the second protective layer 162 may be solder resist layers including an organic polymer material. For example, the first protective layer 161 and the second protective layer 162 may include an epoxy acrylate-based resin. Specifically, the first protective layer 161 and the second protective layer 162 may include a resin, a curing agent, a photo initiator, a pigment, a solvent, a filler, an additive, an acrylic-based monomer, and the like. However, the embodiment is not limited thereto, and the first protective layer 161 and the second protective layer 162 may be any one of a photo solder resist layer, a cover-lay, and a polymer material.

Thicknesses of the first protective layer 161 and the second protective layer 162 may be 1 μm to 20 μm. The thicknesses of the first protective layer 161 and the second protective layer 162 may be 1 μm to 15 μm. For example, the thickness of the first protective layer 161 and the second protective layer 162 may be 5 μm to 20 μm. The thickness of the first protective layer 161 may mean a vertical distance from the lower surface of the third electrode part 143 to the lower surface of the first protective layer 161. Also, the thickness of the second protective layer 162 may mean a vertical distance from the upper surface of the fourth electrode part 144 to the upper surface of the second protective layer 162.

When the thicknesses of the first protective layer 161 and the second protective layer 162 are greater than 20 μm, the thickness of the circuit board may increase. When the thicknesses of the first protective layer 161 and the second protective layer 162 are less than 1 μm, the third electrode part 143 or the fourth electrode part 144 may not be stably protected.

The circuit board of the embodiment includes an insulating substrate, a first substrate layer, and a second substrate layer. Additionally, the circuit board of the embodiment includes a first electrode part disposed on a lower surface of the insulating substrate and a second electrode part disposed on an upper surface of the insulating substrate. At this time, a first substrate layer includes a first insulating layer and a second insulating layer including different materials. At this time, the second insulating layer is disposed closer to the first electrode part than the first insulating layer. Additionally, the first insulating layer includes a first reinforcing fiber and a first filler having a first content. Additionally, the second insulating layer does not include reinforcing fibers and includes a second filler having a second content smaller than the first content. The first insulating layer satisfies the dielectric constant (Dk), dielectric loss (Df), coefficient of thermal expansion (CTE), and Young's modulus (GPa) that the first substrate layer must have. Additionally, the second insulating layer may function to improve fluidity (e.g., resin flowability) of the first substrate layer. For example, when performing a laminating process of the first substrate layer consisting of only the first insulating layer on an insulating substrate, the first substrate layer may not be smoothly filled in a region between the plurality of first electrodes of the first electrode part, and accordingly, the adhesion between the first substrate layer and the first electrode part may be reduced. And, because of this, there is a problem that it is difficult to manufacture circuit boards using a roll-to-roll process. Alternatively, the embodiment allow one insulating layer to include a first insulating layer and a second insulating layer that does not include reinforcing fibers but includes a relatively low content of filler, this allows to improve fluidity in the process of laminating the insulating layer. Through this, the embodiment can secure adhesion between the first electrode part and the first substrate layer, and thereby solve the reliability problem of the first substrate layer being delaminated from the first electrode part. Furthermore, the embodiment can improve fluidity in a process of laminating the insulating layer, and thus it is possible to manufacture circuit boards using a roll-to-roll process. For example, even when a process of laminating an insulating layer is performed using roll-to-roll equipment, the embodiment may laminate the first substrate layer in close contact with the first electrode part. Through this, the embodiment can automate the process of manufacturing a circuit board, thereby reducing manufacturing costs and improving product yield.

Meanwhile, the second substrate layer includes a third insulating layer corresponding to the second insulating layer of the first substrate layer, and a fourth insulating layer corresponding to the first insulating layer of the first substrate layer. Through this, the embodiment can secure fluidity (e.g., resin flowability) in the process of laminating the second substrate layer on the second electrode part, and accordingly, adhesion between the second electrode part and the second substrate layer can be secured.

Additionally, in the embodiment, an upper surface of the first insulating layer or a lower surface of the second insulating layer includes a plurality of first convex parts. In addition, the plurality of first convex parts allow the first substrate layer to smoothly fill a region between the plurality of first electrodes of the first electrode part, in a process of laminating the first substrate layer on the first electrode part. Accordingly, the embodiment can further improve adhesion between the first substrate layer and the first electrode part, and thereby further improve product reliability. Additionally, a plurality of second convex parts are included on a lower surface of the fourth insulating layer or an upper surface of the third insulating layer corresponding to the first substrate layer. Additionally, the plurality of second convex parts allows the second substrate layer to smoothly fill the region between the plurality of second electrodes of the second electrode part, in the process of laminating the second substrate layer on the second electrode part. Accordingly, the embodiment can further improve adhesion between the second substrate layer and the second electrode part, and thereby further improve product reliability.

In addition, at least one of distances between adjacent first convex parts among the plurality of first convex parts in the embodiment includes a region different from at least one of the distances between adjacent second convex parts among the plurality of second convex parts. For example, at least one of the plurality of first convex parts may not vertically overlap with at least one of the plurality of second convex parts. Through this, the embodiment can improve adhesion between a lower roll and the first substrate layer by using at least one of the plurality of second convex parts of the second substrate layer. In addition, the embodiment can improve adhesion between the second substrate layer and an upper roll by using at least one of the plurality of first convex parts of the first substrate layer. Accordingly, the embodiment can further improve the adhesion between the first electrode part and the first substrate layer, and the adhesion between the second electrode part and the second substrate layer.

Meanwhile, a first through part is formed in the first substrate layer of the embodiment. At this time, the first through part includes a first-first part passing through the first insulating layer and a first-second part passing through the second insulating layer. At this time, the first-first part of the first through part has a first slope, and the first-second part has a second slope different from the first slope. For example, an interior angle of the second slope with respect to a lower surface of the first through part is greater than an interior angle of the first slope with respect to a lower surface of the first through part. At this time, a through part in a comparative example includes only the first slope, and accordingly, a width of the upper and lower surfaces of the through part has a “A” level. Alternatively, the first through part of the embodiment includes the first slope and the second slope, and accordingly, a width of the upper surface and the lower surface of the first through part may have a level of “B” smaller than that of the comparative example. Accordingly, the embodiment can minimize a difference between the widths of the upper surface and the lower surface of the first through part, and through this, it is possible to refine a size of the first through part. Furthermore, the embodiment minimizes the loss of a signal transmitting through the first through part by minimizing the difference between the width of the upper surface and the lower surface of the first through part, thereby improving signal characteristics. Additionally, a second through part having a symmetrical shape to the first through part is formed in the second substrate layer. Accordingly, the embodiment can minimize a difference between widths of an upper surface and a lower surface of the second through part, and through this, a size of the second through part can be refined and signal characteristics can be improved.

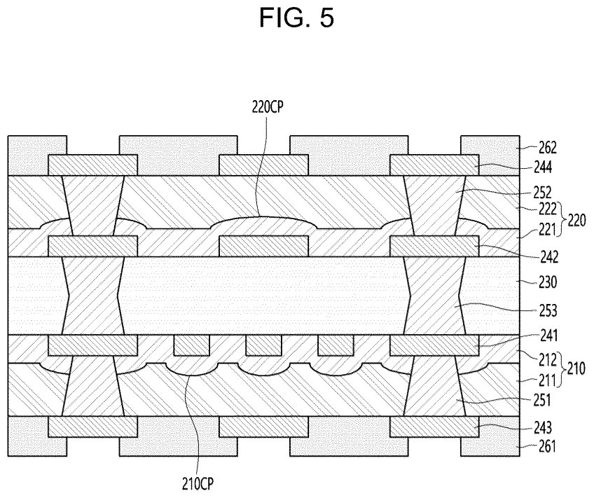

FIG. 5 is a view showing a circuit board according to a second embodiment.

Referring to FIG. 5, the circuit board includes a first substrate layer 210, a second substrate layer 220, and an insulating substrate 230.

The first substrate layer 210 includes a first insulating layer 211 and a second insulating layer 212. Also, the second substrate layer 220 includes a third insulating layer 221 and a fourth insulating layer 222.

In addition, a first electrode part 241 is disposed between a lower surface of the insulating substrate 230 and an upper surface of the second insulating layer 212 of the first substrate layer 210. In addition, a second electrode part 242 is disposed between an upper surface of the insulating substrate 230 and a lower surface of the third insulating layer 221. In addition, a third electrode part 243 is disposed on a lower surface of the first insulating layer 211. In addition, a fourth electrode part 244 is disposed on an upper surface of the fourth insulating layer 222.

In addition, the first through part 251 is formed to pass through the first insulating layer 211 and the second insulating layer 212 of the first substrate layer 210. Also, the second through part 252 is formed to pass through the third insulating layer 221 and the fourth insulating layer 222 of the second substrate layer 220. Also, the third through part 252 is formed to pass through the insulating substrate 230.

In addition, a first protective layer 261 is disposed on a lower surface of the first insulating layer 211. Also, the second protective layer 262 is disposed on an upper surface of the fourth insulating layer 222.

In this case, the circuit board of the second embodiment is substantially the same as the circuit board of the first embodiment of FIG. 2A except for a plurality of first convex parts 210CP formed on an upper surface of the first insulating layer 211 or the lower surface of the second insulating layer 212, and a plurality of second convex parts 220CP formed on an upper surface of the third insulating layer 221 or a lower surface of the fourth insulating layer 222. Hereinafter, a detailed description of the circuit board of the second embodiment that is substantially the same as the circuit board of the first embodiment will be omitted.

Meanwhile, a first convex part 210CP is formed on the upper surface of the first insulating layer 211 or the lower surface of the second insulating layer 212.

In this case, the first convex part 210CP of the second embodiment may be provided to correspond to positions of a plurality of first electrodes constituting the first electrode part 241. For example, an uppermost end of the first convex part of the first embodiment vertically overlaps the region between a plurality of first electrodes. For example, the uppermost end of the first convex part of the first embodiment does not vertically overlap a plurality of first electrodes. Specifically, the first convex part of the first embodiment includes a convex portion toward the insulating substrate.

Alternatively, the first convex part 210CP of the second embodiment may be convex in a direction away from the insulating substrate 230. For example, the first convex part 210CP may be convex toward a lower surface of the first protective layer 261 or the first insulating layer 211. For example, the first convex part 210CP of the second embodiment may also be referred to as a convex part concave toward the insulating substrate 230.

The first convex part 210CP of the second embodiment may vertically overlap a plurality of first electrodes of the first electrode part 241. For example, an outer region of a convex portion of the first convex part 210CP may not vertically overlap a plurality of first electrodes of the first electrode part 241. For example, an outer region of the convex portion of the first convex part 210CP may vertically overlap a region between the plurality of first electrodes. In addition, a lowermost end of the convex portion of the first convex part 210CP may vertically overlap the first electrode part 241. For example, the first convex part 210CP may be formed to correspond to positions of a plurality of first electrodes of the first electrode part 241. For example, the first convex part 210CP may vertically overlap a plurality of first electrodes of the first electrode part 241. In addition, in the second embodiment, adhesion between the first substrate layer 210 and the first electrode part 241 may be improved using the first convex part 210CP in the process of laminating the first substrate layer 210. Accordingly, it is possible to laminate the first substrate layer 210 in a state of being stably adhered even by a roll-to-roll process.

Specifically, the first convex part 210CP is convex in a direction away from the first electrode part 241 while vertically overlapping the first electrode part 241. Accordingly, a portion of the upper surface of the first insulating layer 211 positioned between the plurality of first convex parts 210CP may be adjacent to the first electrode part 241 compared to the first convex part 210CP. In addition, the second embodiment may improve the fluidity in the process of laminating the first substrate layer 210 on the first electrode part 241 by a portion between the plurality of first convex parts 210CP. In the first embodiment, for example, the fluidity is improved in the laminate process as the plurality of first convex parts 110CPs are convex toward the plurality of first electrode parts. Alternatively, the second embodiment may improve the fluidity in the laminate process as a region between the plurality of first convex parts 210CPs is convex toward the plurality of first electrode parts 241.

In addition, a second convex part 220CP is formed on the upper surface of the third insulating layer 221 or the lower surface of the fourth insulating layer 222. In this case, the second convex part 220CP of the second embodiment may correspond to positions of a plurality of second electrodes constituting the second electrode part 242. For example, a lowermost end of the second convex part of the first embodiment vertically overlaps a region between a plurality of second electrodes. For example, a lowermost end of the second convex part of the first embodiment does not vertically overlap a plurality of second electrodes. Specifically, the second convex part of the first embodiment includes a convex portion toward the insulating substrate.

Alternatively, the second convex part 220CP of the second embodiment may be convex in a direction away from the insulating substrate 230. For example, the second convex part 220CP may be convex toward the upper surface of the second protective layer 262 or the fourth insulating layer 222. For example, the second convex part 220CP of the second embodiment may also be referred to as a concave part concave with respect to the insulating substrate 230.

The second convex part 220CP of the second embodiment may vertically overlap a plurality of second electrodes of the second electrode part 242. For example, an outer region of a convex portion of the second convex part 220CP may not vertically overlap a plurality of second electrodes of the second electrode part 242. For example, an outer region of the convex portion of the second convex part 220CP may vertically overlap a region between the plurality of second electrodes. Also, an uppermost end of the convex portion of the second convex part 220CP may vertically overlap the second electrode part 242. For example, the second convex part 220CP may be formed to correspond to positions of a plurality of second electrodes of the fourth insulating layer 222. For example, the second convex part 220CP may vertically overlap a plurality of first electrodes of the second electrode part 242. In addition, the second embodiment may improve the adhesion between the second substrate layer 220 and the second electrode part 242 using the second convex part 220CP in the process of laminating the second substrate layer 220.

Specifically, the second convex part 220CP is convex in a direction away from the second electrode part 242 while vertically overlapping the second electrode part 242. Accordingly, a portion of a lower surface of the fourth insulating layer 222 between the plurality of second convex parts 220CP may be adjacent to the second electrode part 242 compared to the second convex part 220CP. And, in the second embodiment, fluidity in a process of laminating the second substrate layer 220CP on the second electrode part 242 may be improved by a portion between the plurality of second convex parts 220CP.

On the other hand, at least one of distances between the first convex parts 210CPs adjacent to each other in the second embodiment may include a region different from at least one of distances between the second convex parts 220CPs adjacent to each other.

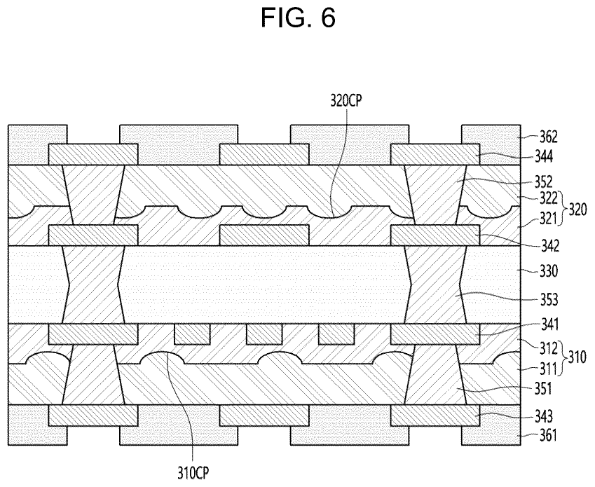

FIG. 6 is a view showing a circuit board according to a third embodiment.

Referring to FIG. 6, the circuit board includes a first substrate layer 310, a second substrate layer 320, and an insulating substrate 330.

The first substrate layer 310 includes a first insulating layer 311 and a second insulating layer 312. In addition, the second substrate layer 320 includes a third insulating layer 321 and a fourth insulating layer 322.

In addition, a first electrode part 341 is disposed between a lower surface of the insulating substrate 330 and an upper surface of the second insulating layer 312 of the first substrate layer 310. In addition, a second electrode part 342 is disposed between an upper surface of the insulating substrate 330 and a lower surface of the third insulating layer 321. Also, a third electrode part 343 is disposed on a lower surface of the first insulating layer 311. Also, a fourth electrode part 344 is disposed on an upper surface of the fourth insulating layer 322.

In addition, the first through part 351 is formed to pass through the first insulating layer 311 and the second insulating layer 312 of the first substrate layer 310. In addition, the second through part 352 is formed to pass through the third insulating layer 321 and the fourth insulating layer 322 of the second substrate layer 320. In addition, the third through part 352 is formed to pass through the insulating substrate 330.

Also, a first protective layer 361 is disposed on a lower surface of the first insulating layer 311. Also, a second protective layer 362 is disposed on an upper surface of the fourth insulating layer 322.

In this case, the circuit board of the third embodiment is substantially the same as the circuit board of the first embodiment of FIG. 2A except for a plurality of first convex parts 310CP formed on an upper surface of the first insulating layer 311 or a lower surface of the second insulating layer 312, and a plurality of second convex parts 320CP formed on an upper surface of the third insulating layer 321 or a lower surface of the fourth insulating layer 322. Hereinafter, a detailed description of the circuit board of the second embodiment substantially the same as that of the circuit board of the first embodiment will be omitted.

Meanwhile, a first convex part 310CP is formed on the upper surface of the first insulating layer 311 or the lower surface of the second insulating layer 312.

In this case, the first convex part 110CP of the first embodiment is formed to correspond to a topology of the first electrode part 141. For example, a plurality of first convex parts 110CP of the first embodiment are formed at positions vertically overlapping a plurality of first electrodes of the first electrode part 141.

Alternatively, the first convex part 310CP of the third embodiment may be formed regardless of a topology of the first electrode part 341.

For example, an upper surface of the first insulating layer 311 or a lower surface of the second insulating layer 312 of the third embodiment includes a plurality of first convex parts 310CPs that are convex toward the insulating substrate 330 or the first electrode part 341.

And, at least one of the plurality of first convex parts 310CP may vertically overlap at least one of the plurality of first electrodes of the first electrode part 341. Specifically, an uppermost end of at least one of the plurality of first convex parts 310CP may vertically overlap at least one of the plurality of first electrodes of the first electrode part 341.

In addition, at least one of the plurality of first convex parts 310CP may not vertically overlap at least one of the plurality of first electrodes of the first electrode part 341. Specifically, an uppermost end of at least one other first convex part among the plurality of first convex parts 310CP may vertically overlap a region between the plurality of first electrodes of the first electrode part 341 without vertically overlapping the plurality of first electrodes.

And, the first convex part 310CP may be formed in advance on the upper surface of the first insulating layer 311 or the lower surface of the second insulating layer 312 before the first substrate layer is laminated. And, in the third embodiment, adhesion with the plurality of first electrode parts 341 may be improved using the first convex part 310CP in a process of laminating the first insulating layer 311 and the second insulating layer 312.

Meanwhile, a second convex part 320CP is formed on the upper surface of the third insulating layer 321 or the lower surface of the fourth insulating layer 322.

In this case, the second convex part 120CP of the first embodiment is formed to correspond to the topology of the second electrode part 142. For example, a plurality of second convex parts 120CP of the first embodiment are formed at positions vertically overlapping a plurality of second electrodes of the second electrode part 142.

Alternatively, the second convex part 320CP of the third embodiment may be formed regardless of the topology of the second electrode part 342.

For example, the upper surface of the third insulating layer 321 or the lower surface of the fourth insulating layer 322 of the third embodiment includes a plurality of second convex parts 320CPs that are convex toward the insulating substrate 330 or the second electrode part 342.

And, at least one of the plurality of second convex parts 320CP may vertically overlap at least one of the plurality of second electrodes of the second electrode part 342. Specifically, a lowermost end of at least one second convex part of the plurality of second convex parts 320CP may vertically overlap at least one of the plurality of second electrodes of the second electrode part 342.

In addition, at least one of the plurality of second convex parts 320CPs may not vertically overlap at least one of the plurality of second electrodes of the second electrode part 342. Specifically, a lowermost end of at least one other second convex part of the plurality of second convex parts 320CPs may vertically overlap a region between the plurality of second electrodes without vertically overlapping the plurality of second electrodes of the second electrode part 342.

In addition, the second convex part 320CP may be formed in advance on the upper surface of the third insulating layer 321 or the lower surface of the fourth insulating layer 322 before the second substrate layer is laminated. And, in the third embodiment, adhesion with the plurality of second electrode parts 342 may be improved using the second convex part 320CP in the process of laminating the third insulating layer 321 and the fourth insulating layer 322.

On the other hand, at least one of distances between the first convex parts 310CPs adjacent to each other in the third embodiment may include a region different from at least one of distances between the second convex parts adjacent to each other among the plurality of second convex parts 320CPs.

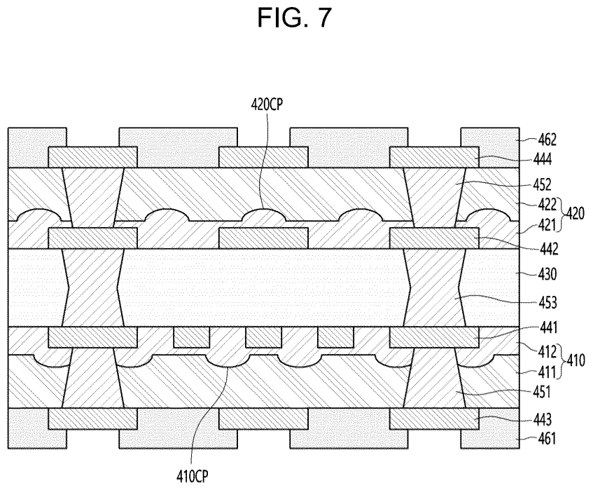

FIG. 7 is a view showing a circuit board according to a fourth embodiment.

Referring to FIG. 7, the circuit board includes a first substrate layer 410, a second substrate layer 420, and an insulating substrate 430.

The first substrate layer 410 includes a first insulating layer 411 and a second insulating layer 412. Also, the second substrate layer 420 includes a third insulating layer 421 and a fourth insulating layer 422.

Also, a first electrode part 441 is disposed between a lower surface of the insulating substrate 430 and an upper surface of the second insulating layer 412 of the first substrate layer 410. Also, a second electrode part 442 is disposed between an upper surface of the insulating substrate 430 and a lower surface of the third insulating layer 421. Also, a third electrode part 443 is disposed on a lower surface of the first insulating layer 411. Also, a fourth electrode part 444 is disposed on an upper surface of the fourth insulating layer 422.

Also, the first through part 451 is formed to pass through the first insulating layer 411 and the second insulating layer 412 of the first substrate layer 410. Also, the second through part 452 is formed to pass through the third insulating layer 421 and the fourth insulating layer 422 of the second substrate layer 420. Also, the third through part 452 is formed to pass through the insulating substrate 430.

Also, a first protective layer 461 is disposed on a lower surface of the first insulating layer 411. Also, a second protective layer 462 is disposed on an upper surface of the fourth insulating layer 422.

In this case, the circuit board of the fourth embodiment is substantially the same as the circuit board of the second embodiment of FIG. 5 except for a plurality of first convex parts 410CP formed on an upper surface of the first insulating layer 411 or a lower surface of the second insulating layer 412, and a plurality of second convex parts 420CP formed on an upper surface of the third insulating layer 421 or a lower surface of the fourth insulating layer 422. Accordingly, hereinafter, a detailed description of the circuit board of the fourth embodiment, which is substantially the same as the circuit board of the second embodiment, will be omitted.

Meanwhile, a first convex part 410CP is formed on the upper surface of the first insulating layer 411 or the lower surface of the second insulating layer 412. In this case, the first convex part 210CP of the second embodiment is formed to correspond to the topology of the first electrode part 241. For example, a plurality of first convex parts 210CP of the second embodiment are formed at positions vertically overlapping a plurality of first electrodes of the first electrode part 241.

Unlike this, the first convex part 410CP of the fourth embodiment may be formed regardless of the topology of the first electrode part 441.

For example, the upper surface of the first insulating layer 411 or the lower surface of the second insulating layer 412 of the fourth embodiment includes a plurality of first convex parts 410CPs that are convex (e.g., convex toward the lower surface of the first insulating layer or the first protective layer) in a direction away from the insulating substrate 430 or the first electrode part 441.

And, at least one of the plurality of first convex parts 410CP may vertically overlap at least one of the plurality of first electrodes of the first electrode part 441. Specifically, a lowermost end of at least one first convex part of the plurality of first convex parts 410CP may vertically overlap at least one of the plurality of first electrodes of the first electrode part 441.

Also, at least one of the plurality of first convex parts 410CP may not vertically overlap at least one of the plurality of first electrodes of the first electrode part 441. Specifically, a lowermost end of at least one other first convex part among the plurality of first convex parts 410CP may vertically overlap a region between the plurality of first electrodes of the first electrode part 441 without vertically overlapping the plurality of first electrodes.

And, the first convex part 410CP may be formed in advance on the upper surface of the first insulating layer 411 or the lower surface of the second insulating layer 412 before the first substrate layer is laminated. And, in the fourth embodiment, adhesion with the first electrode part 441 may be improved using the first convex part 410CP in the process of laminating the first insulating layer 411 and the second insulating layer 412.

Meanwhile, a second convex part 420CP is formed on the upper surface of the third insulating layer 421 or the lower surface of the fourth insulating layer 422.

In this case, the second convex part 220CP of the second embodiment is formed to correspond to the topology of the second electrode part 242. For example, a plurality of second convex parts 220CP of the second embodiment are formed at positions vertically overlapping a plurality of second electrodes of the second electrode part 242.

Unlike this, the second convex part 420CP of the fourth embodiment may be formed regardless of the topology of the second electrode part 442.

For example, the upper surface of the third insulating layer 421 or the lower surface of the fourth insulating layer 422 of the fourth embodiment includes a plurality of second convex parts 420CPs that are convex toward the insulating substrate 430 or the second electrode part 442.

And, at least one of the plurality of second convex parts 420CP may vertically overlap at least one of the plurality of second electrodes of the second electrode part 442. Specifically, an uppermost end of at least one second convex part of the plurality of second convex parts 420CP may vertically overlap at least one of the plurality of second electrodes of the second electrode part 442.

In addition, at least one of the plurality of second convex parts 420CP may not vertically overlap at least one of the plurality of second electrodes of the second electrode part 442. Specifically, an uppermost end of at least one other second convex part of the plurality of second convex parts 420CP may vertically overlap the region between the plurality of second electrodes of the second electrode part 442 without vertically overlapping the plurality of second electrodes.

And, the second convex part 420CP may be formed in advance on the upper surface of the third insulating layer 421 or the lower surface of the fourth insulating layer 422 before the second substrate layer is laminated. And, in the fourth embodiment, adhesion with the plurality of second electrode parts 442 may be improved using the second convex part 420CP in the process of laminating the third insulating layer 421 and the fourth insulating layer 422.

In addition, at least one of distances between the first convex parts adjacent to each other among the plurality of first convex parts 410CPs may include a region different from at least one of the distances between the second convex parts adjacent to each other among the plurality of second convex parts 420CPs.

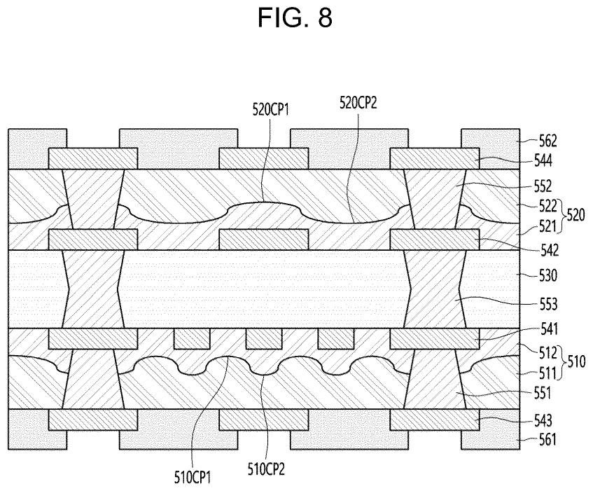

FIG. 8 is a view showing a circuit board according to a fifth embodiment.]

Referring to FIG. 8, the circuit board includes a first substrate layer 510, a second substrate layer 520, and an insulating substrate 530.

The first substrate layer 510 includes a first insulating layer 511 and a second insulating layer 512. Also, the second substrate layer 520 includes a third insulating layer 521 and a fourth insulating layer 522.

In addition, a first electrode part 541 is disposed between a lower surface of the insulating substrate 530 and an upper surface of the second insulating layer 512 of the first substrate layer 510. In addition, a second electrode part 542 is disposed between an upper surface of the insulating substrate 530 and a lower surface of the third insulating layer 521. In addition, a third electrode part 543 is disposed on a lower surface of the first insulating layer 511. In addition, a fourth electrode part 544 is disposed on an upper surface of the fourth insulating layer 522.

In addition, the first through part 551 is formed to pass through the first insulating layer 511 and the second insulating layer 512 of the first substrate layer 510. In addition, the second through part 552 is formed to pass through the third insulating layer 521 and the fourth insulating layer 522 of the second substrate layer 520. In addition, the third through part 552 is formed to pass through the insulating substrate 530.

Also, a first protective layer 561 is disposed on a lower surface of the first insulating layer 511. Also, a second protective layer 562 is disposed on an upper surface of the fourth insulating layer 522.

In this case, the circuit board of the fifth embodiment may include a plurality of first convex parts formed on the upper surface of the first insulating layer 511 or the lower surface of the second insulating layer 512. For example, the plurality of first convex parts may include regions convex in different directions. For example, the first convex part may include a first region 510CP1 convex toward the first electrode part 541 and a second region 510CP2 convex in a direction away from the first electrode part 541. For example, the first region 510CP1 of the first convex part may be a convex part with respect to the first electrode part 541, and the second region 510CP2 of the first convex part may be a concave part with respect to the first electrode part 541. On the contrary, the first region 510CP1 of the first convex part may be referred to as a concave part with respect to the lower surface of the first insulating layer or the first protective layer, and the second region 510CP2 of the first convex part may be referred to as a convex part with respect to the lower surface of the first insulating layer or the first protective layer.

Also, the circuit board of the fifth embodiment may include a plurality of second convex parts formed on the upper surface of the third insulating layer 521 or the lower surface of the fourth insulating layer 522. For example, the plurality of second convex parts may include regions convex in different directions. For example, the second convex part may include a third region 520CP1 convex toward the upper surface of the fourth insulating layer 522 or the second protective layer 562, and a fourth region 520CP2 convex toward the first electrode part 541. For example, the third region 520CP1 of the second convex part may be referred to as a concave part with respect to the second electrode part 542, and the fourth region 520CP2 of the second convex part may be referred to as a convex part with respect to the second electrode part 542. On the contrary, the third region 520CP1 of the second convex part may be referred to as a convex part with respect to the upper surface of the fourth insulating layer or the second protective layer, and the fourth region 520CP2 of the second convex part may be referred to as a concave part with respect to the upper surface of the fourth insulating layer 522 or the second protective layer 562.

Meanwhile, at least one of distances between the first regions 510CP1 adjacent to each other of the plurality of first regions 510CP1 of the first convex part may include a region different from at least one of distances between the third regions adjacent to each other of the plurality of third regions 520CP1 of the second convex part. Also, at least one of distances between the first regions 510CP1 adjacent to each other of the plurality of first regions 510CP1 of the first convex part may include a region different from at least one of distances between the fourth regions adjacent to each other of the plurality of fourth regions 520CP2 of the second convex part.

In addition, at least one of distances between the second regions adjacent to each other among the plurality of second regions 510CP2 of the first convex part may include a different region from at least one of distances between the third regions adjacent to each other among the plurality of third regions 520CP1 of the second convex part. In addition, at least one of distances between the second regions adjacent to each other among the plurality of second regions 510CP2 of the first convex part may include a region different from at least one of distances between the fourth regions adjacent to each other among the plurality of fourth regions 520CP2 of the second convex part above.

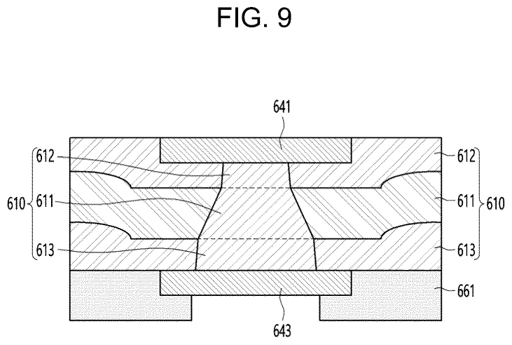

FIG. 9 is a view showing a circuit board according to a fifth embodiment.

Before explaining FIG. 9, each of the first substrate layer and the second substrate layer of the previous embodiment includes two insulating layers.

Alternatively, a first substrate layer and a second substrate layer of the circuit board of the fifth embodiment may each include three insulating layers. Hereinafter, only the first substrate layer will be described. However, the second substrate layer may also have a layer structure corresponding to the first substrate layer described below.

A first substrate layer 610 may include second insulating layers disposed on both sides thereof, respectively, with the first insulating layer 611 interposed therebetween. For example, the second insulating layer of the first substrate layer 610 may include a second-first insulating layer 612 disposed on the first insulating layer 611 and a second-second insulating layer 613 disposed under the first insulating layer 611.

In addition, the first insulating layer 611 and the second-first insulating layer 612 correspond to the first insulating layer and the second insulating layer described in the previous embodiment, and accordingly, the description will be omitted.

The first substrate layer of the fifth embodiment may further include a second-second insulating layer 613 disposed under the first insulating layer 611. The second-second insulating layer 613 may include the same material as the second-first insulating layer 612. For example, the second-second insulating layer 613 may include only a filler of a second content, without including a reinforcing fiber.

Meanwhile, the second-second insulating layer 613 may further improve adhesion with an additional substrate layer when the additional substrate layer is laminated under the first substrate layer. For example, the additional substrate layer may also have a layer structure corresponding to the first substrate layer. For example, the additional substrate layer may include a fifth insulating layer corresponding to the first insulating layer of the first substrate layer and a sixth insulating layer corresponding to the second insulating layer of the first substrate layer. In this case, the sixth insulating layer of the additional substrate layer may include only a second content of a filler without including a reinforcing fiber. In this case, when the sixth insulating layer is laminated directly under the first insulating layer, adhesion to each other may decrease due to a difference in the coefficient of thermal expansion between the first insulating layer and the sixth insulating layer. In this case, in the embodiment, a second-second insulating layer is additionally disposed under the first insulating layer as described above, and through this, the sixth insulating layer may be in contact with the second-second insulating layer rather than the first insulating layer. Accordingly, the embodiment may further improve the adhesion between the first substrate layer and the additional substrate layer.

Meanwhile, the circuit board of the fifth embodiment includes a first through part 651 passing through the first substrate layer 610. In this case, the first through part 651 may be divided into three parts. For example, the first through part 651 may include a first-first part 651-1 passing through the first insulating layer 611, a first-second part 651-2 passing through the second-first insulating layer 611, and a first-third part 651-3 passing through g the second-second insulating layer 613. And, the first-first part 651-1 may have a first slope whose width gradually decreases toward the first electrode part 641. Also, the first-second part 651-2 may have a second slope different from the first slope while the width gradually decreases toward the first electrode part 641. Also, the first-third part 651-3 may have a third slope different from the first slope while the width gradually decreases toward the first electrode part 641. In this case, the second-first insulating layer 611 and the second-second insulating layer 613 include the same material. Accordingly, the third slope of the first-third part 651-3 may correspond to the second slope of the first-second part 651-2.

Meanwhile, the circuit boards of the first to fifth embodiments described above may have different shapes of the first convex part and the second convex part, or may have different insulation layer structures of at least one of the first substrate layer and the second substrate layer. However, an embodiment is not limited to the structures of the first to fifth embodiments illustrated in the drawings, and a circuit board having a new structure by a combination thereof may be provided. For example, the first convex part of the first substrate layer may include the first convex part according to the first embodiment, and the second convex part of the second substrate layer may include the second convex part according to any one of the second to fourth embodiments.

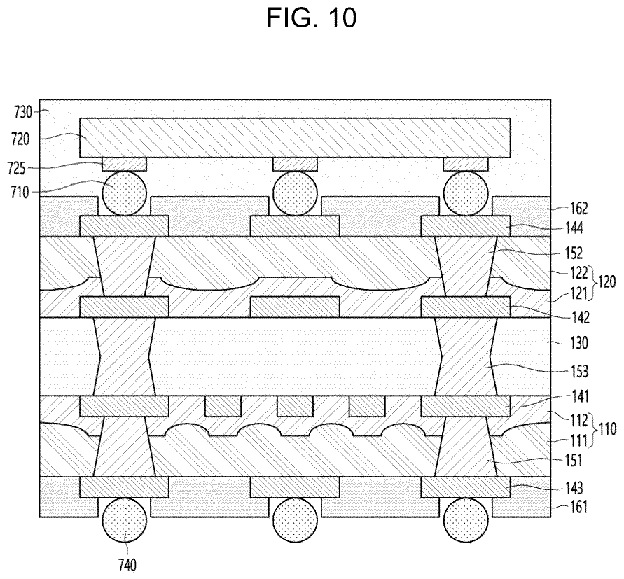

FIG. 10 is a view showing a semiconductor package according to an embodiment.

Referring to FIG. 10, the package substrate may include a chip mounted on a circuit board included in any one of the drawings of FIGS. 2A to 9. Hereinafter, a semiconductor package including the circuit board of FIG. 2A will be described. However, the embodiment is not limited thereto, and a semiconductor package may be implemented using the circuit board included in any one of the drawings of FIGS. 5 to 9.

The semiconductor package of the embodiment includes a circuit board, at least one chip mounted on the circuit board, a molding layer molding the chip, and a connection part for connecting the chip or an external substrate.

For example, the semiconductor package may include a first connection part 710 disposed on the fourth electrode part 144 disposed on an uppermost side of the circuit board. A cross section of the first connection part 710 may have a circular shape or a semicircular shape. For example, the cross section of the first connection part 710 may have a partially or entirely rounded shape. The cross-sectional shape of the first connection part 710 may be a flat surface on one side and a curved surface on the other side. The first connection part 710 may be a solder ball, but is not limited thereto.

Meanwhile, an embodiment may include a chip 720 disposed on the first connection part 710. The chip 720 may be a processor chip. For example, the chip 720 may be an application processor (AP) chip among a central processor (e.g., a CPU), a graphic processor (e.g., a GPU), a digital signal processor, an encryption processor, a microprocessor, and a microcontroller. A terminal 725 of the chip 720 may be connected to the fourth electrode part 144 through the first connection part 710. For example, the fourth electrode part 144 may include a mounting pad on which the chip 720 is mounted.

Also, although not illustrated in the drawings, the semiconductor package of the embodiment may further include an additional chip. In an embodiment, at least two chips of a central processor (e.g., a CPU), a graphics processor (e.g., a GPU), a digital signal processor, an encryption processor, a microprocessor, and a microcontroller may be disposed on the circuit board with a predetermined distance, respectively. For example, the chip 720 of the embodiment may include a central processor chip and a graphics processor chip, but is not limited thereto.

Meanwhile, the plurality of chips may be spaced apart from each other by a predetermined distance on the circuit board. For example, a separation distance between the plurality of chips may be 150 μm or less. For example, the separation distance between the plurality of chips may be 120 μm or less. For example, the separation distance between the plurality of chips may be 100 μm or less.

Preferably, the separation distance between the plurality of chips may have a range of 60 μm to 150 μm. Preferably, the separation distance between the plurality of chips may have a range of 70 μm to 120 μm. Preferably, the separation distance between the plurality of chips may have a range of 80 μm to 110 μm. When the separation distance between the plurality of chips is less than 60 μm, a problem in operation reliability may occur due to interference between the plurality of chips. When the separation distance between the plurality of chips is greater than 150 μm, a signal transmission loss may increase as a distance between the plurality of chips is increased. When the separation distance between the plurality of chips is greater than 150 μm, the volume of the semiconductor package may increase.

The semiconductor package may include a molding layer 730. The molding layer 730 may be disposed to cover the chip 720. For example, the molding layer 730 may be an epoxy mold compound (EMC) formed to protect the mounted chip 720, but is not limited thereto.

In this case, the molding layer 730 may have a low dielectric constant to enhance heat dissipation characteristics. For example, the dielectric constant (Dk) of the molding layer 730 may range from 0.2 to 10. For example, the dielectric constant (Dk) of the molding layer 730 may range from 0.5 to 8. For example, the dielectric constant (Dk) of the molding layer 730 may range from 0.8 to 5. Accordingly, an embodiment allows the molding layer 730 to have a low dielectric constant so that heat dissipation characteristics with respect to heat generated from the chip 720 may be improved.

Meanwhile, the semiconductor package may include a second connection part 740 disposed at a lowermost side of the circuit board. The second connection part 740 may be disposed on a lower surface of the third electrode part 143 exposed through the first protective layer 161.

### —Method of Manufacturing the Circuit Board—

Hereinafter, a method of manufacturing a circuit board according to an embodiment will be described.

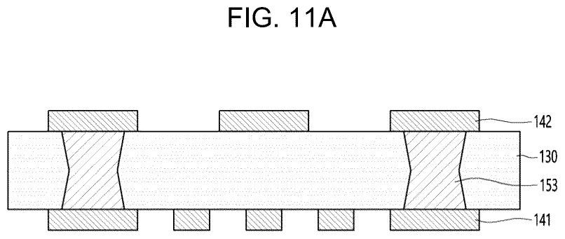

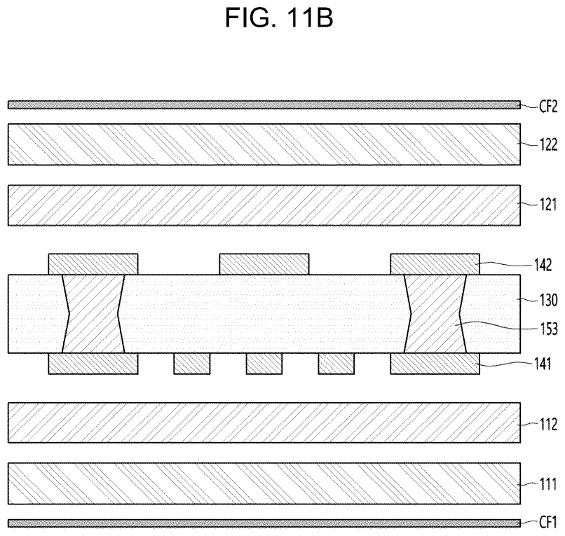

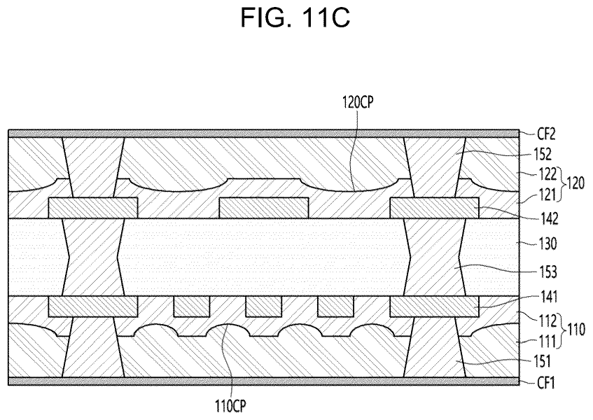

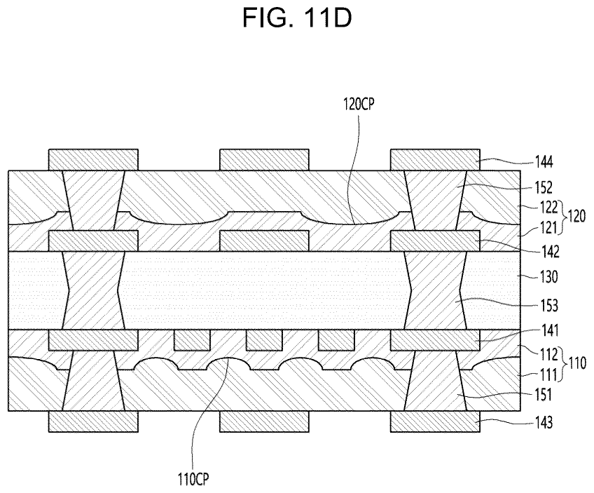

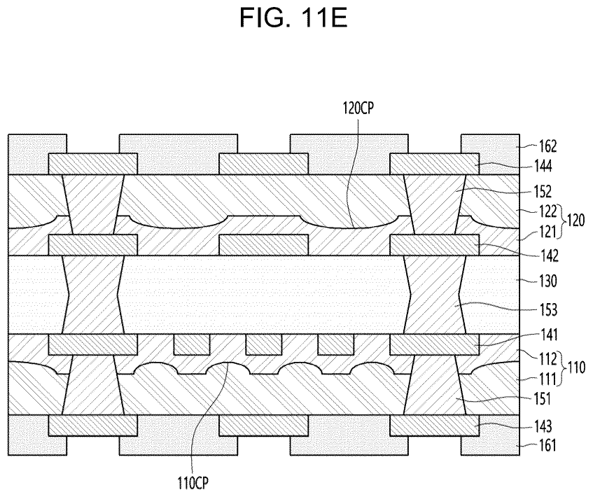

FIGS. 11A to 11E are views for explaining a method of manufacturing the circuit board shown in FIG. 2A in order of processes.

Referring to FIG. 11A, according to an embodiment, a process of preparing an insulating substrate 130 may be performed. The insulating substrate 130 may be a copper clad laminate (CCL), but is not limited thereto.

Next, an embodiment may proceed with a process of forming a through hole in the insulating substrate 130. The through hole may be formed by performing a first laser process on the upper side of the insulating substrate 130 and a second laser process on a lower side of the insulating substrate 130. However, an embodiment is not limited thereto, and the through hole may be formed by performing only one laser process on one side of the insulating substrate according to the thickness or material of the insulating substrate 130.

Thereafter, the embodiment may proceed with a process of forming a seed layer (not shown) on an upper surface of the insulating substrate 130, a lower surface of the insulating substrate 130, and the inner wall of the through hole. Next, in an embodiment, electroplating is performed using the seed layer. Accordingly, the embodiment may proceed with a process of forming a first electrode part 141 on the lower surface of the insulating substrate 130, forming a second electrode part 142 on the upper surface of the insulating substrate 130, and forming a third through part 153 filling the through hole. In this case, when the first electrode part 141, the second electrode part 142, and the third through part 153 are formed, a process of etching and removing the seed layer may be performed.

Next, as shown in FIG. 11B, the embodiment performs a process of disposing a first insulating layer 111, a second insulating layer 112, and a first copper foil layer CF1 under the insulating substrate 130. In addition, the embodiment proceeds with the process of disposing the third insulating layer 121, the fourth insulating layer 122, and the second copper foil layer CF2 on the insulating substrate 130. In this case, the second insulating layer 112 and the third insulating layer 121 adjacent to the first electrode part 141 and the second electrode part 142 do not include reinforcing fibers and include only a relatively low second content of a filler. In this case, although not illustrated in the drawings, a first convex part 110CP may be formed on the upper surface or the lower surface of the first insulating layer 111 or the second insulating layer 112, or may not be formed differently. In addition, a second convex part 120CP may be formed on the upper surface of the third insulating layer 121 or the lower surface of the fourth insulating layer 122, and may not be formed differently.

Next, as shown in FIG. 11C, the embodiment may proceed with a process of laminating the first substrate layer 110 under the insulating substrate 130 and laminating the second substrate layer 120 on the insulating substrate 130 in a sequential arrangement state as described above. In this case, a general laminate process may be applied to the lamination process, and unlike this, a roll-to-roll process may be performed. And, the embodiment may enable stable lamination not only by a general lamination process but also by a roll-to-roll process, by using the first substrate layer 110 and the second substrate layer 120 each having a two-layer structure.

In this case, the upper surface of the first insulating layer 111 or the lower surface of the second insulating layer 112 after the lamination process may include a plurality of first convex parts 110CP formed in advance before the lamination process or formed after the lamination process. In addition, the upper surface of the third insulating layer 121 or the lower surface of the fourth insulating layer 122 after the lamination process may include a plurality of second convex parts 120CP formed before the lamination process or formed after the lamination process. In an embodiment, the adhesion between the first electrode part 141 and the first substrate layer 110 may be secured by using the first convex part 110CP, and the adhesion between the second electrode part 142 and the second substrate layer 120 may be secured by using the second convex part 120CP.

Next, as shown in FIG. 11D, in an embodiment, a process of forming the first through part 151, the second through part 152, the third electrode part 143, and the fourth electrode part 144 may be performed. In this case, the process of forming the first through part 151, the second through part 152, the third electrode part 143, and the fourth electrode part 144 may be performed in a state in which the first copper foil layer CF1 and the second copper foil layer CF2 are laminated, but unlike this, the process may be performed after the first copper foil layer CF1 and the second copper foil layer CF2 are removed.

Next, as shown in FIG. 11E, an embodiment may proceed with a process of forming a first protective layer 161 including a first opening vertically overlapping at least one of a plurality of third electrodes of the third electrode part 143. Also, the embodiment may proceed with a process of forming a second protective layer 162 including a second opening vertically overlapping at least one of a plurality of fourth electrodes of the fourth electrode part 144.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other. Furthermore, when the circuit board having the above-described characteristics of the invention is used in a transportation device such as a vehicle, it is possible to transmit a high-current signal required by the vehicle at a high speed, thereby improving the safety of the transportation device. Furthermore, the circuit board and the semiconductor package including the same can be operated normally even in an unexpected situation occurring in various driving environments of the transportation device, thereby safely protecting the driver.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a first insulating layer;
a second insulating layer disposed on the first insulating layer;
a first electrode part disposed on the second insulating layer;
a second electrode part disposed on the first electrode part;
a third insulating layer disposed on the second electrode part; and
a fourth insulating layer disposed on the third insulating layer,
wherein an upper surface of the first insulating layer includes a plurality of first convex parts,
wherein a lower surface of the fourth insulating layer includes a plurality of second convex parts, and
wherein at least one of distances between adjacent first convex parts among the plurality of first convex parts includes a region different from at least one of distances between adjacent second convex parts among the plurality of second convex parts.

2. The circuit board of claim 1, wherein the first convex part is convex toward the first electrode part, and
wherein the second convex part is convex toward the second electrode part.

3. The circuit board of claim 1, wherein the first electrode part includes a plurality of first electrodes spaced apart from each other along a horizontal direction, and
wherein the second electrode part includes a plurality of second electrodes spaced apart from each other along the horizontal direction,
wherein the plurality of first convex parts vertically overlap at least one of the plurality of second electrodes, and
wherein the plurality of second convex parts vertically overlap at least one of the plurality of first electrodes.

4. The circuit board of claim 3, wherein each of the plurality of first convex parts is positioned between the plurality of first electrodes, and
wherein each of the plurality of second convex parts is positioned between the plurality of second electrodes.

5. The circuit board of claim 1, wherein the second insulating layer and the third insulating layer do not include glass fibers, and
wherein the first insulating layer and the fourth insulating layer include glass fibers.

6. The circuit board of claim 1, wherein each of the first to fourth insulating layers includes a filler,
wherein a filler content of the first insulating layer is higher than that of the second insulating layer, and
wherein a filler content of the fourth insulating layer is higher than that of the third insulating layer.

7. The circuit board of claim 1, further comprising:
an insulating substrate disposed between the first electrode part and the second electrode part.

8. The circuit board of claim 1, further comprising:
a third electrode part disposed under the first insulating layer; and
a fourth electrode part disposed on the fourth insulating layer.

9. The circuit board of claim 8, further comprising:
a first through part disposed in the first insulating layer and the second insulating layer; and
a second through part disposed in the third insulating layer and the fourth insulating layer,
wherein the first through part connects the first electrode part and the third electrode part, and
wherein the second through part connects the fourth electrode part and the second electrode part.

10. The circuit board of claim 9, wherein the first through part includes:
a first-first part passing through the first insulating layer and having a first slope whose width gradually decreases toward the upper surface of the first insulating layer; and
a first-second part passing through the second insulating layer and having a second slope different from the first slope whose width gradually decreases toward the upper surface of the second insulating layer.

11. The circuit board of claim 10, wherein an interior angle between a lower surface of the first through part and the first slope is smaller than an interior angle between the lower surface of the first through part and the second slope.

12. The circuit board of claim 9, wherein the second through part includes:
a second-first part passing through the third insulating layer and having a third slope whose width gradually increases toward an upper surface of the third insulating layer; and
a second-second part passing through the fourth insulating layer and having a fourth slope different from the third slope whose width gradually increases toward the upper surface of the fourth insulating layer.

13. The circuit board of claim 12, wherein an interior angle between a lower surface of the second through part and the third slope is smaller than an interior angle between the lower surface of the second through part and the fourth slope.

14. The circuit board of claim 1, wherein a lower surface of the first insulating layer includes a region in which a height changes to correspond to the plurality of first convex parts, and
wherein an uppermost end of the lower surface of the first insulating layer is positioned lower than a lower surface of the first electrode part.

15. The circuit board of claim 8, wherein the second insulating layer includes:
a second-first insulating layer disposed on the first insulating layer; and
a second-second insulating layer disposed under the first insulating layer,
wherein the first electrode part is disposed on the second-first insulating layer, and
wherein the third electrode part is disposed under the second-second insulating layer.

16. The circuit board of claim 8, wherein the third insulating layer includes:
a third-first insulating layer disposed under the fourth insulating layer; and
a third-second insulating layer disposed on the fourth insulating layer,
wherein the second electrode part is disposed under the third-first insulating layer, and
wherein the fourth electrode part is disposed on the third-second insulating layer.

17. The circuit board of claim 1, wherein an upper surface of the third insulating layer includes a region in which a height changes to correspond to the plurality of second convex parts, and
wherein a lowermost end of the upper surface of the third insulating layer is positioned higher than an upper surface of the second electrode part.

18. A semiconductor package substrate comprising:
a first insulating layer;
a second insulating layer disposed on the first insulating layer;
a first electrode part disposed on the second insulating layer;
a second electrode part disposed on the first electrode part;
a third insulating layer disposed on the second electrode part;
a fourth insulating layer disposed on the third insulating layer;
a third electrode part disposed under the first insulating layer;
a fourth electrode part disposed on the fourth insulating layer;
a connection part disposed on at least one of a plurality of fourth electrodes of the fourth electrode part; and
a chip mounted on the connection part,
wherein an upper surface of the first insulating layer includes a plurality of first convex parts,
wherein a lower surface of the fourth insulating layer includes a plurality of second convex parts,
wherein a least one of distances between the first convex parts adjacent to each other among the plurality of first convex parts includes a region different from at least one of the distances between the second convex parts adjacent to each other among the plurality of second convex parts.

19. The semiconductor package substrate of claim 18, wherein the first convex part is convex toward the first electrode part, and
wherein the second convex part is convex toward the second electrode part.

20. The semiconductor package substrate of claim 18, wherein the first electrode part includes a plurality of first electrodes spaced apart from each other in a horizontal direction,
wherein the second electrode part includes a plurality of second electrodes spaced apart from each other in the horizontal direction,
wherein the plurality of first convex parts vertically overlap at least one of the plurality of second electrodes, and
wherein the plurality of second convex parts vertically overlap at least one of the plurality of first electrodes.
